(19) United States
(12) Patent Application Publication
(10) Pub. No.: US 2017/0317213 A1
(43) Pub. Date: Nov. 2, 2017

(54) SEMICONDUCTOR DEVICES

(71) Applicant: Samsung Electronics Co., Ltd., Suwon-si (KR)

(72) Inventors: Mi-Seon PARK, Daegu (KR); Gi-Gwan PARK, Hwaseong-si (KR); Tae-Jong LEE, Hwaseong-si (KR); Yong-Suk TAK, Seoul (KR); Ki-Yeon PARK, Hwaseong-si (KR)

(73) Assignee: Samsung Electronics Co., Ltd., Suwon-si (KR)

(21) Appl. No.: 15/410,238

(22) Filed: Jan. 19, 2017

(30) Foreign Application Priority Data
Apr. 28, 2016 (KR) 10-2016-0051912

(51) Int. Cl. H01L 29/78; H01L 29/66; H01L 29/06; H01L 21/02

(52) U.S. Cl. CPC H01L 29/7851; H01L 29/66795; H01L 29/6656; H01L 29/66545; H01L 21/0214; H01L 21/0228; H01L 21/0217; H01L 29/0649

(57) ABSTRACT

A semiconductor device includes an active fin on a substrate, a gate structure on the active fin, a gate spacer structure directly on a sidewall of the gate structure, and a source/drain layer on a portion of the active fin adjacent the gate spacer structure. The gate spacer structure includes a silicon oxycarbonitride (SiOCN) pattern and a silicon dioxide (SiO₂) pattern sequentially stacked.

### CROSS-REFERENCE TO RELATED APPLICATION

This application claims priority under 35 USC §119 to Korean Patent Application No. 10-2016-0051912, filed on Apr. 28, 2016 in the Korean Intellectual Property Office (KIPO), the contents of which are herein incorporated by reference in their entirety.

### BACKGROUND

### 1. Field

Example embodiments relate to semiconductor devices. For example, at least some example embodiments relate to semiconductor devices including spacers on sidewalls of a gate structure.

### 2. Description of the Related Art

A finFET may have a spacer on a sidewall of a gate structure, and the spacer may include a nitride, e.g., silicon nitride. Silicon nitride may have a high dielectric constant and low band gap energy, and thus may be vulnerable to leakage current.

### SUMMARY

Example embodiments provide a semiconductor device having good characteristics.

According to example embodiments, there is provided a semiconductor device. The semiconductor device may include an active fin on a substrate; a gate structure on the active fin; a gate spacer structure directly on a sidewall of the gate structure, the gate spacer structure including a silicon oxycarbonitride (SiOCN) pattern and a silicon dioxide (SiO₂) pattern sequentially stacked; and a source/drain layer on a portion of the active fin adjacent the gate spacer structure.

According to example embodiments, there is provided a semiconductor device. The semiconductor device may include an active fin on a substrate; a gate structure on the active fin; a gate spacer structure on the active fin such that the gate spacer structure covers a sidewall of the gate structure; and a source/drain layer on a portion of the active fin adjacent the gate spacer structure. The gate spacer structure may include, a diffusion prevention pattern on the active fin, a silicon oxycarbonitride pattern on the diffusion prevention pattern, the silicon oxycarbonitride pattern including a cross-section taken along a direction having an L-like shape, an outgassing prevention pattern on the silicon oxycarbonitride pattern, the outgassing prevention pattern including a cross-section taken along the direction having an L-like shape, and an offset pattern on the outgassing prevention pattern.

According to example embodiments, there is provided a semiconductor device. The semiconductor device may include a substrate; an active region protruding from an upper surface of the substrate; and a gate spacer on a sidewall of a gate, the gate spacer being a multi-layer structure including an offset pattern having silicon dioxide.

In the semiconductor device in accordance with example embodiments, the gate spacer structure may include the offset pattern having a dielectric constant lower than that of silicon nitride or silicon oxycarbonitride, and having a band gap higher than that of silicon nitride or silicon oxycarbonitride. Thus, a leakage current through the gate spacer structure may be reduced, and a parasitic capacitance between the gate structures may be reduced. Accordingly, the semiconductor device may have good electrical characteristics.

### BRIEF DESCRIPTION OF THE DRAWINGS

Example embodiments will be more clearly understood from the following detailed description taken in conjunction with the accompanying drawings. FIGS. 1 to 77 represent non-limiting, example embodiments as described herein.

FIGS. 1 to 36 are plan views and cross-sectional views illustrating stages of a method of manufacturing a semiconductor device in accordance with example embodiments;

FIG. 37 is a cross-sectional view illustrating a semiconductor device in accordance with example embodiments;

FIGS. 38 to 75 are plan views and cross-sectional views illustrating stages of a method of manufacturing a semiconductor device in accordance with example embodiments; and

FIGS. 76 and 77 are cross-sectional views illustrating a semiconductor device in accordance with example embodiments.

### DESCRIPTION OF EMBODIMENTS

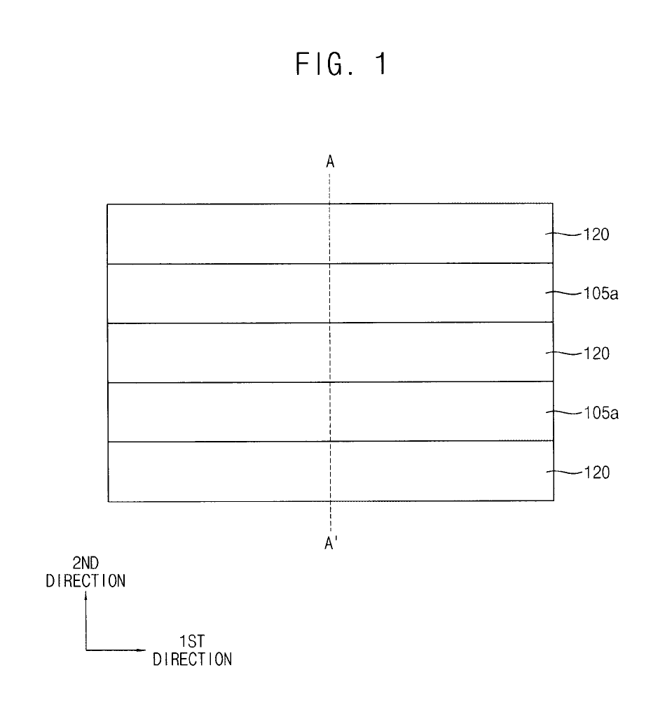

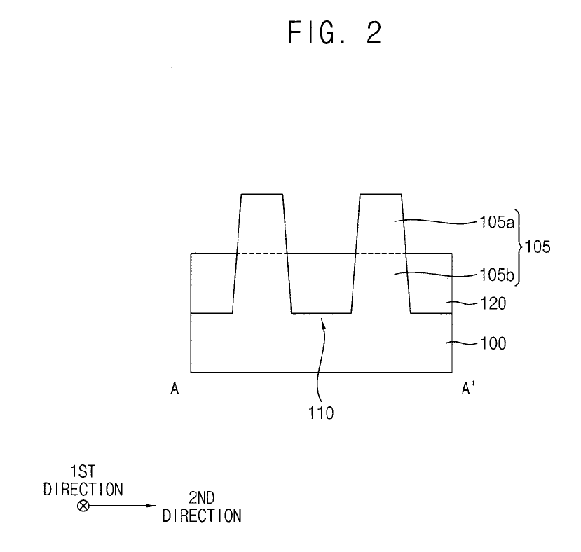

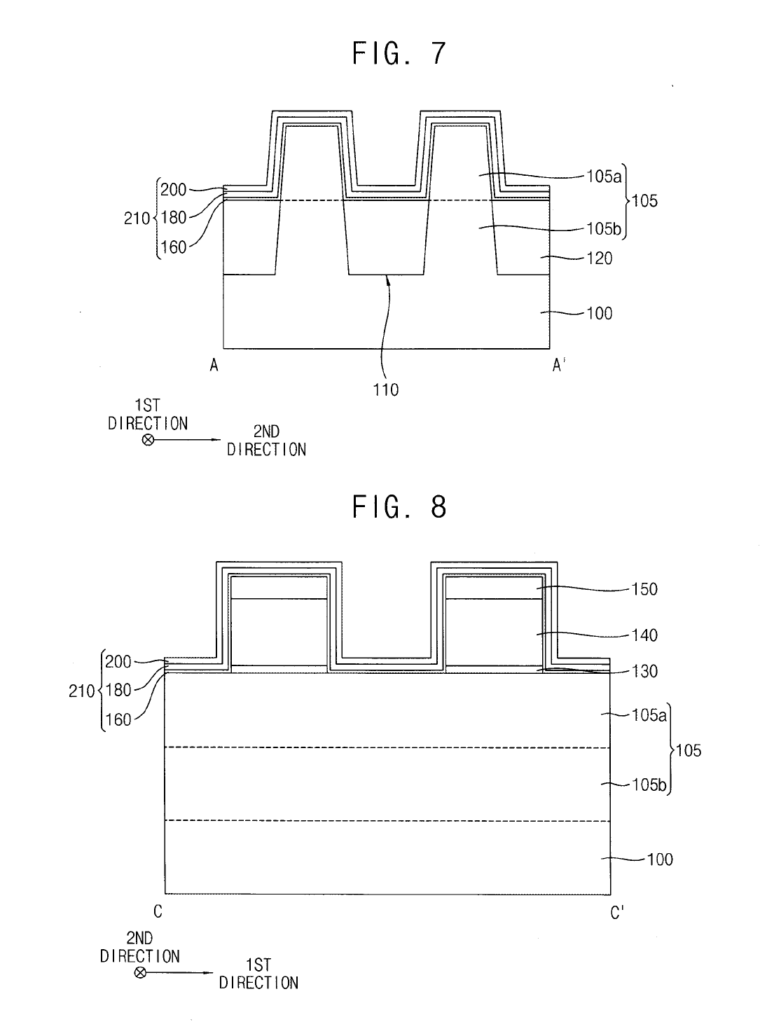

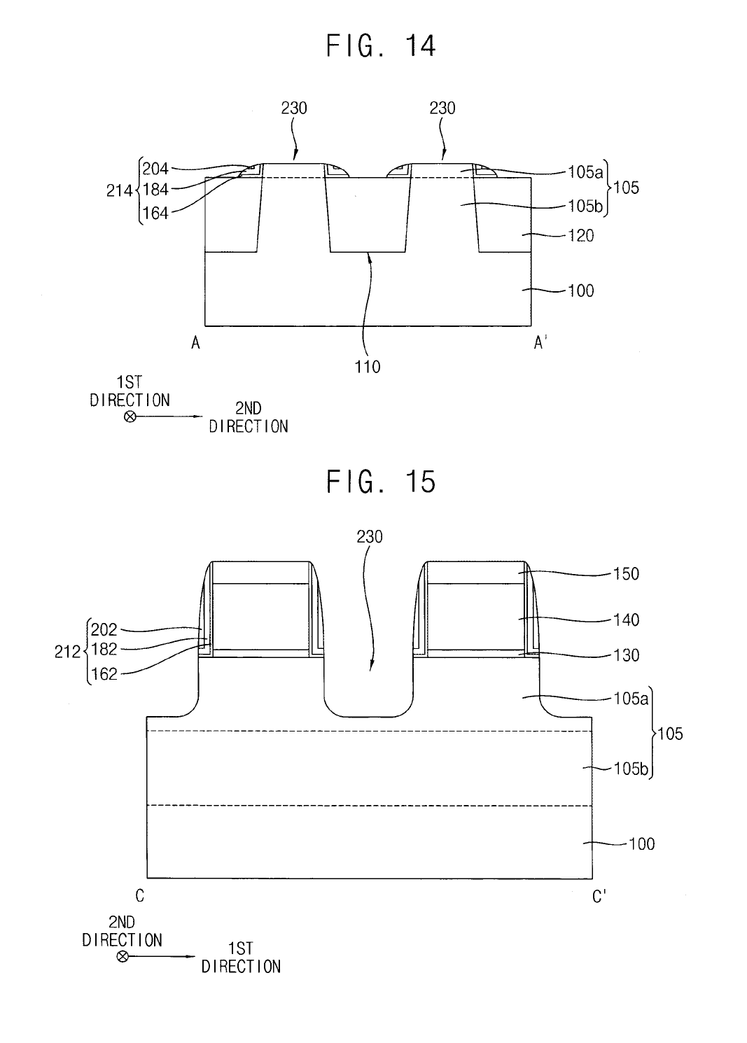

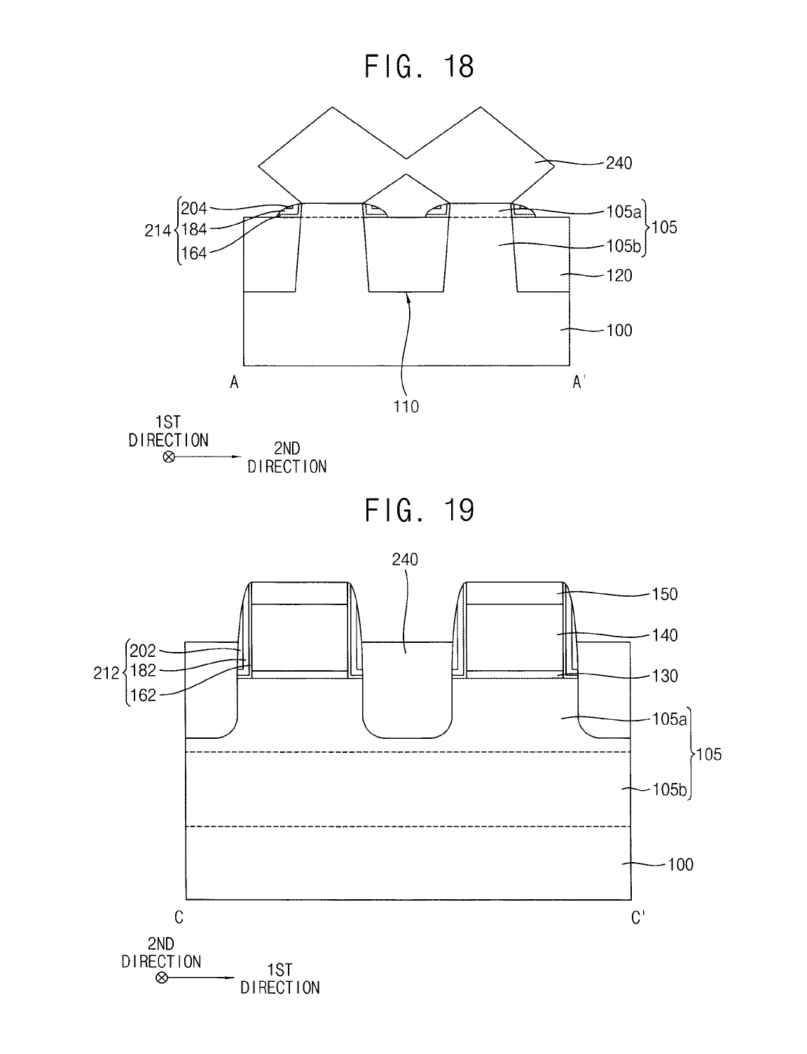

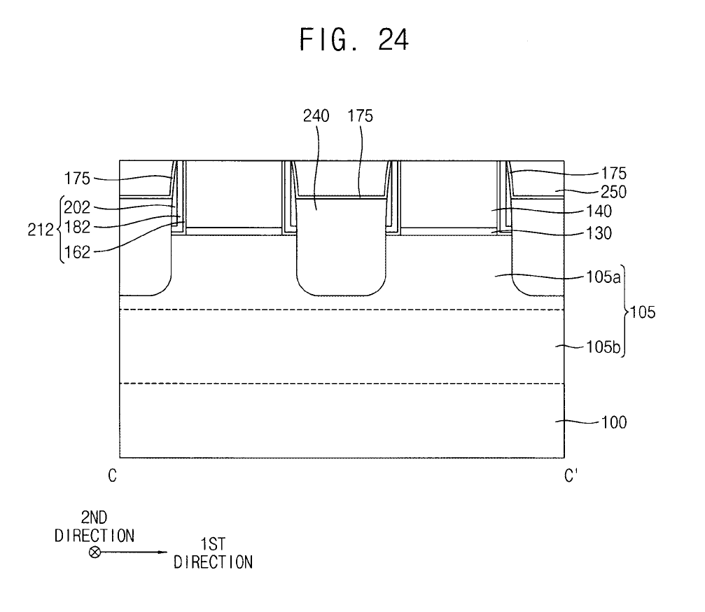

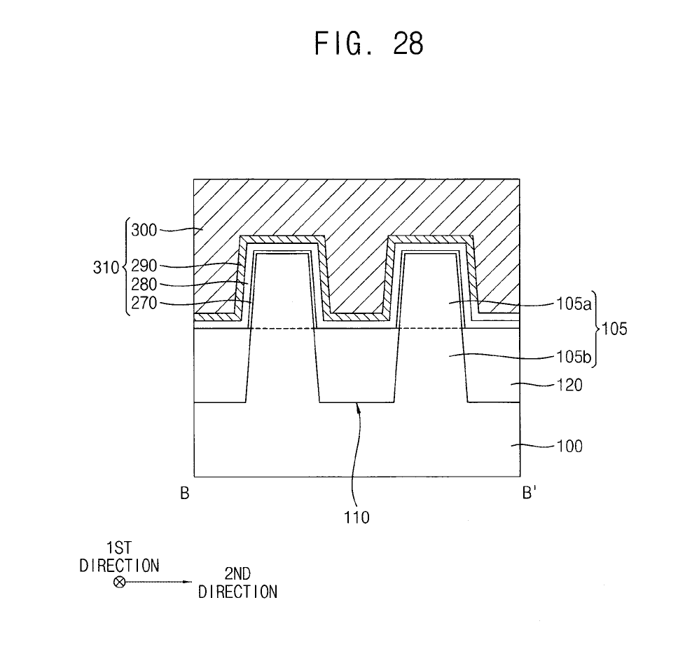

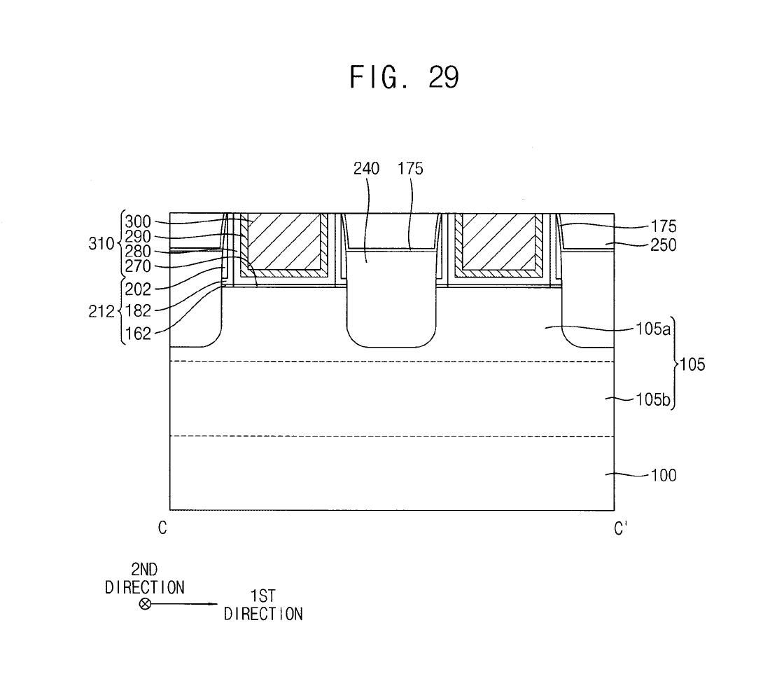

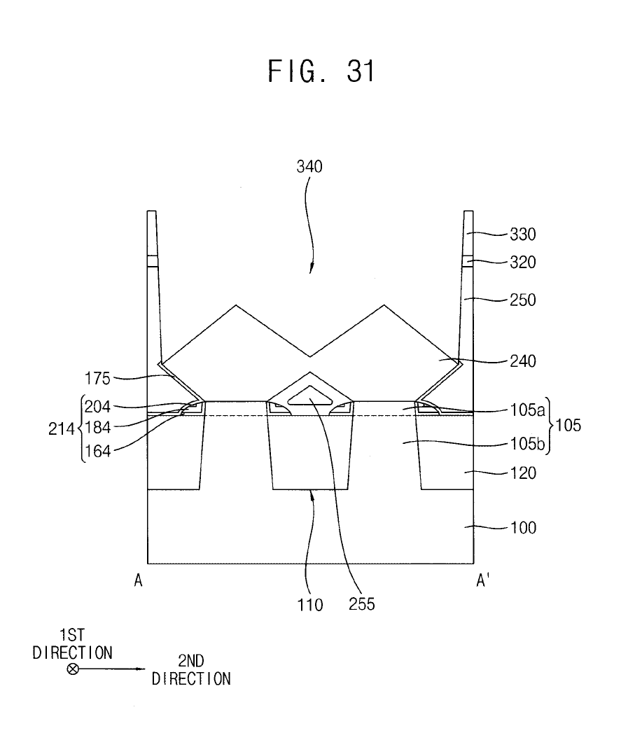

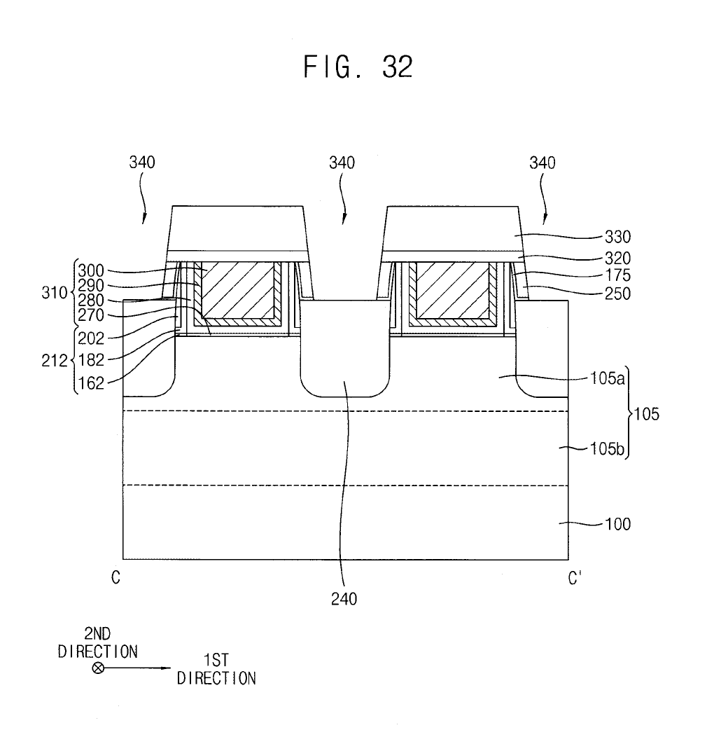

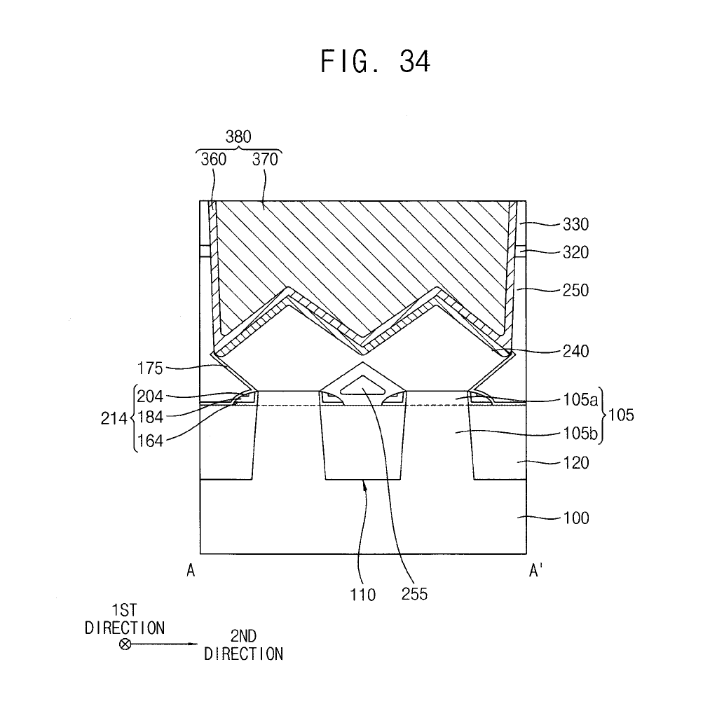

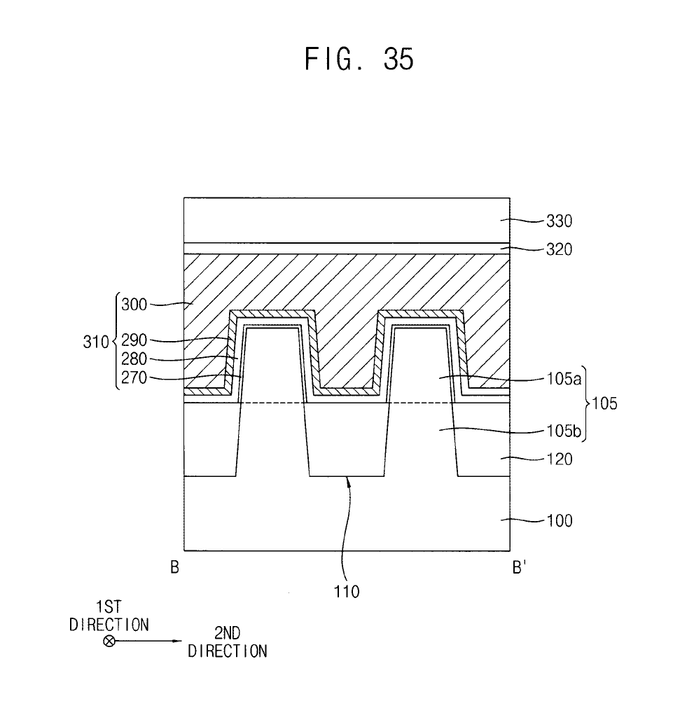

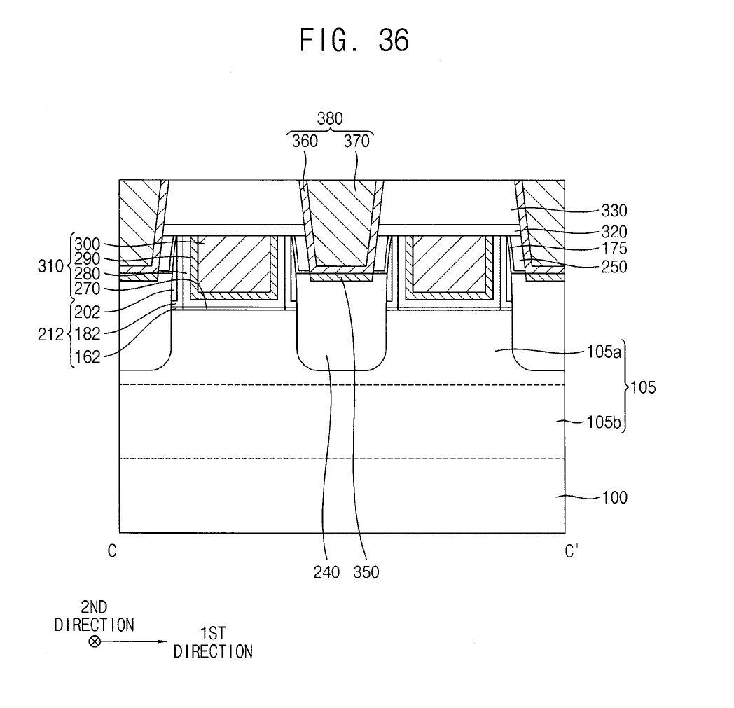

FIGS. 1 to 36 are plan views and cross-sectional views illustrating stages of a method of manufacturing a semiconductor device in accordance with example embodiments. Particularly, FIGS. 1, 3, 6, 9, 13, 17, 22, 25, 27, 30 and 33 are plan views, and FIGS. 2, 4-5, 7-8, 10-12, 14-16, 18-21, 23-24, 26, 28-29, 31-32 and 34-36 are cross-sectional views.

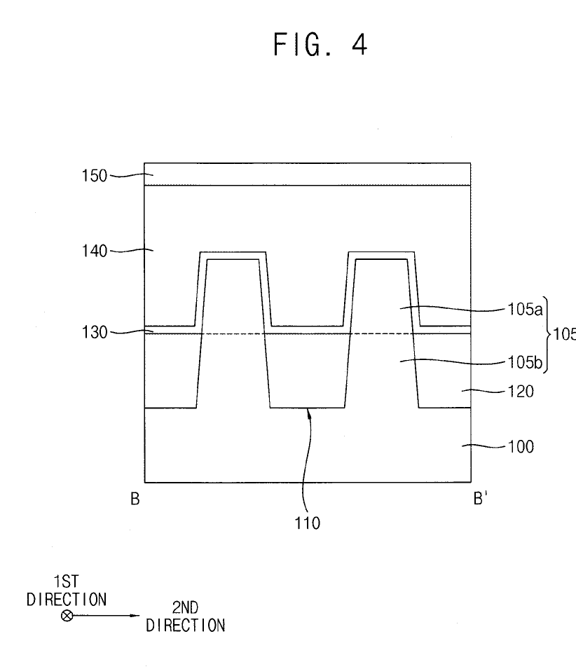

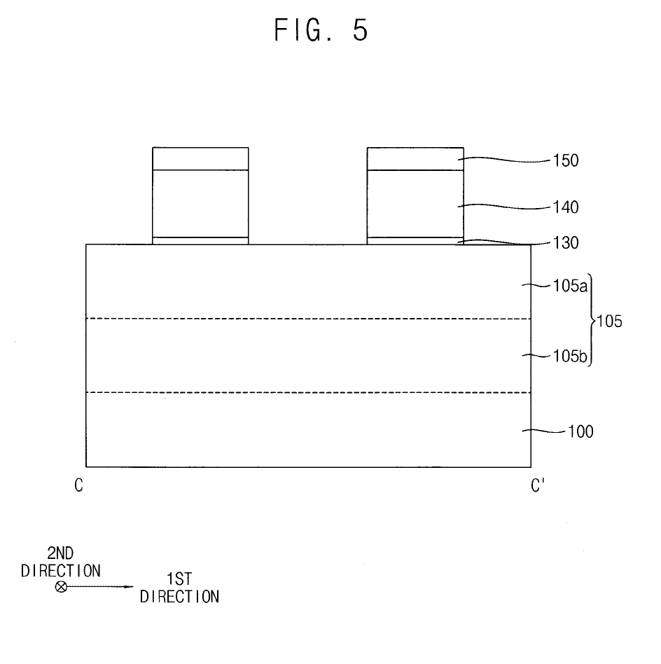

FIGS. 2, 7, 10, 14, 16, 18, 20, 23, 31 and 34 are cross-sectional views taken along lines A-A′ of corresponding plan views, respectively, FIGS. 4, 28 and 35 are cross-sectional views taken along lines B-B′ of corresponding plan views, respectively, and FIGS. 5, 8, 11, 12, 15, 19, 21, 24, 26, 29, 32 and 36 are cross-sectional views taken along lines C-C′ of corresponding plan views, respectively.

Referring to FIGS. 1 and 2, an upper portion of a substrate 100 may be partially etched to form a first recess 110, and an isolation pattern 120 may be formed to fill a lower portion of the first recess 110.

The substrate 100 may include a semiconductor material, e.g., silicon, germanium, silicon-germanium, etc., or III-V semiconductor compounds, e.g., GaP, GaAs, GaSb, etc. In some embodiments, the substrate 100 may be a silicon-on-insulator (SOI) substrate, or a germanium-on-insulator (GOI) substrate.

As the first recess 110 is formed on the substrate 100, an active region 105 may be defined on the substrate 100. The active region 105 may protrude from an upper surface of the substrate 100, and thus may be also referred to as an active fin. A region of the substrate 100 on which the active fin 105 is not formed may be referred to as a field region.

In example embodiments, the active fin 105 may extend in a first direction substantially parallel to the upper surface of the substrate 100, and a plurality of active fins 105 may be formed in a second direction, which may be substantially parallel to the upper surface of the substrate 100 and cross the first direction. In example embodiments, the first and second directions may cross each other at a right angle, and thus may be substantially perpendicular to each other.

In example embodiments, the isolation pattern 120 may be formed by forming an isolation layer on the substrate 100 to sufficiently fill the first recess 110, planarizing the isolation layer until the upper surface of the substrate 100 may be exposed, and removing an upper portion of the isolation layer to expose an upper portion of the first recess 110. The isolation layer may be formed of an oxide, e.g., silicon oxide.

As the isolation pattern 120 is formed on the substrate 100, the active fin 105 may be divided into a lower active pattern 105b whose sidewall may be covered by the isolation pattern 120, and an upper active pattern 105a not covered by the isolation pattern 120 but protruding therefrom. In example embodiments, the upper active pattern 105a may have a width in the second direction that may be slightly less than a width of the lower active pattern 105b.

In example embodiments, the isolation pattern 120 may be formed to have a multi-layered structure. Particularly, the isolation pattern 120 may include first and second liners (not shown) sequentially stacked on an inner wall of the first recess 110, and a filling insulation layer (not shown) filling a remaining portion of the first recess 110 on the second liner. For example, the first liner may be formed of an oxide, e.g., silicon oxide, the second liner may be formed of a nitride, e.g., silicon nitride, or polysilicon, and the filling insulation layer may be formed of an oxide, e.g., silicon oxide.

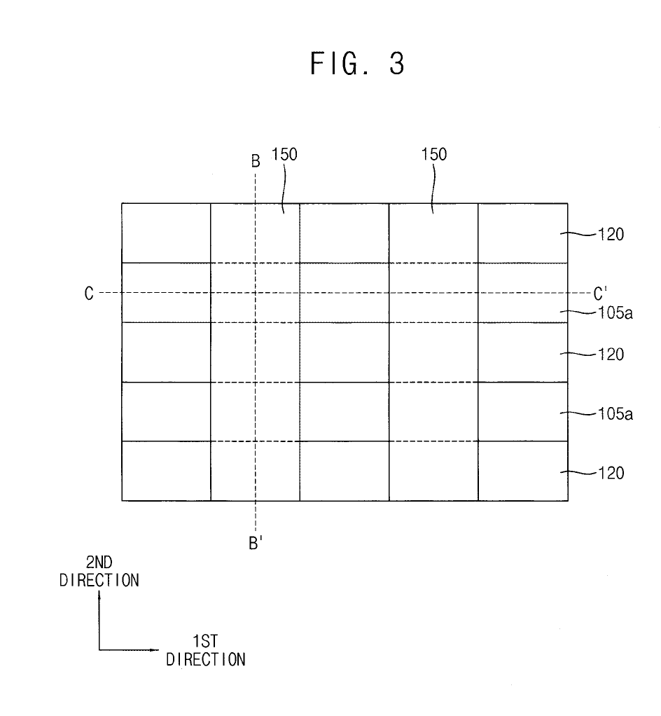

Referring to FIGS. 3 to 5, a dummy gate structure may be formed on the substrate 100.

Particularly, the dummy gate structure may be formed by sequentially forming a dummy gate insulation layer, a dummy gate electrode layer and a dummy gate mask layer on the substrate 100 and the isolation pattern 120, patterning the dummy gate mask layer to form a dummy gate mask 150, and sequentially etching the dummy gate electrode layer and the dummy gate insulation layer using the dummy gate mask 150 as an etching mask.

Thus, the dummy gate structure may include a dummy gate insulation pattern 130, a dummy gate electrode 140 and the dummy gate mask 150 sequentially stacked on the substrate 100.

The dummy gate insulation layer may be formed of an oxide, e.g., silicon oxide, the dummy gate electrode layer may be formed of, e.g., polysilicon, and the dummy gate mask layer may be formed of a nitride, e.g., silicon nitride.

The dummy gate insulation layer may be formed by a chemical vapor deposition (CVD) process, an atomic layer deposition (ALD) process, etc. Alternatively, the dummy gate insulation layer may be formed by a thermal oxidation process on an upper portion of the substrate 100, and in this case, the dummy gate insulation layer may be formed only on the upper active pattern 105a. The dummy gate electrode layer and the dummy gate mask layer may be formed by a CVD process, an ALD process, etc.

In example embodiments, the dummy gate structure may be formed to extend in the second direction, and a plurality of dummy gate structures may be formed in the first direction.

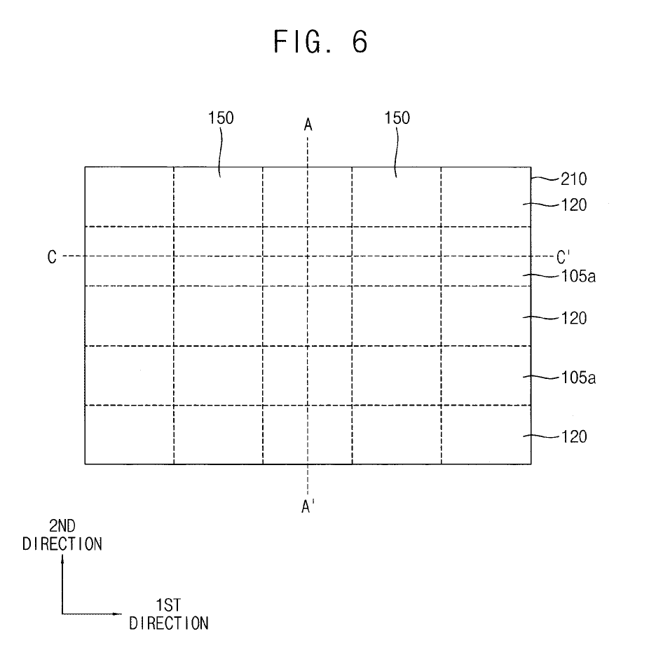

Referring to FIGS. 6 to 8, a spacer layer structure 210 may be formed on the active fin 105 of the substrate 100 and the isolation pattern 120 to cover the dummy gate structure.

In example embodiments, the spacer layer structure 210 may include a diffusion prevention layer 160, a spacer layer 180, and an offset layer 200 sequentially stacked.

The diffusion prevention layer 160 may reduce or prevent components of the spacer layer 180 from diffusing into the active fin 105. For example, when the spacer layer 180 includes carbon, the carbon in the spacer layer 180 may be prevented by the diffusion prevention layer 160 from diffusing into the active fin 105, and thus the active fin 105 may not be carbonized. The diffusion prevention layer 160 may be formed of, e.g., silicon nitride.

The spacer layer 180 may not be removed by a wet etching process subsequently performed but remain, and may include a material having a dielectric constant less than that of silicon nitride (SiN). In example embodiments, the spacer layer 180 may be formed of silicon oxycarbonitride (SiOCN).

The offset layer 200 may compensate a thickness of a gate spacer structure 212, which may be formed by anisotropically etching the spacer layer structure 212 subsequently, so that the gate spacer structure 212 may have a desired thickness. The offset layer 200 may be formed of material having a dielectric constant less than and a band gap more than that of silicon nitride or silicon oxycarbonitride, e.g., silicon dioxide (SiO₂).

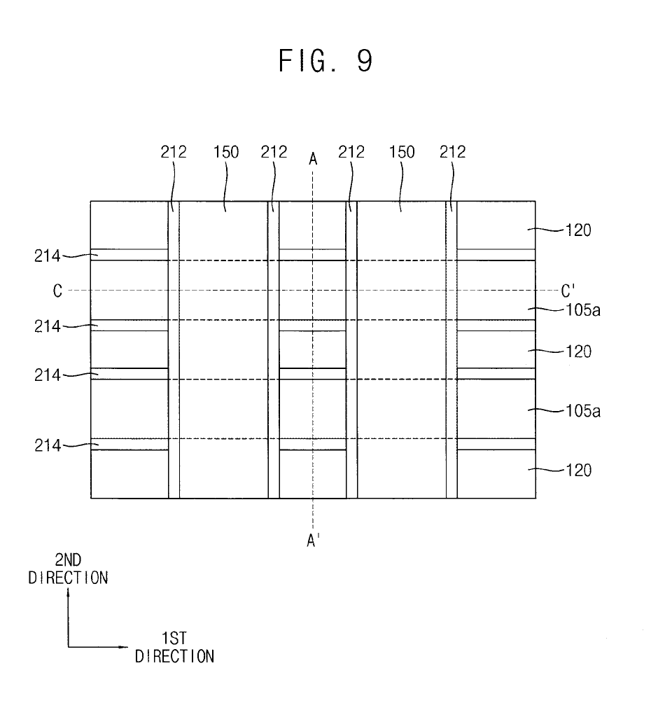

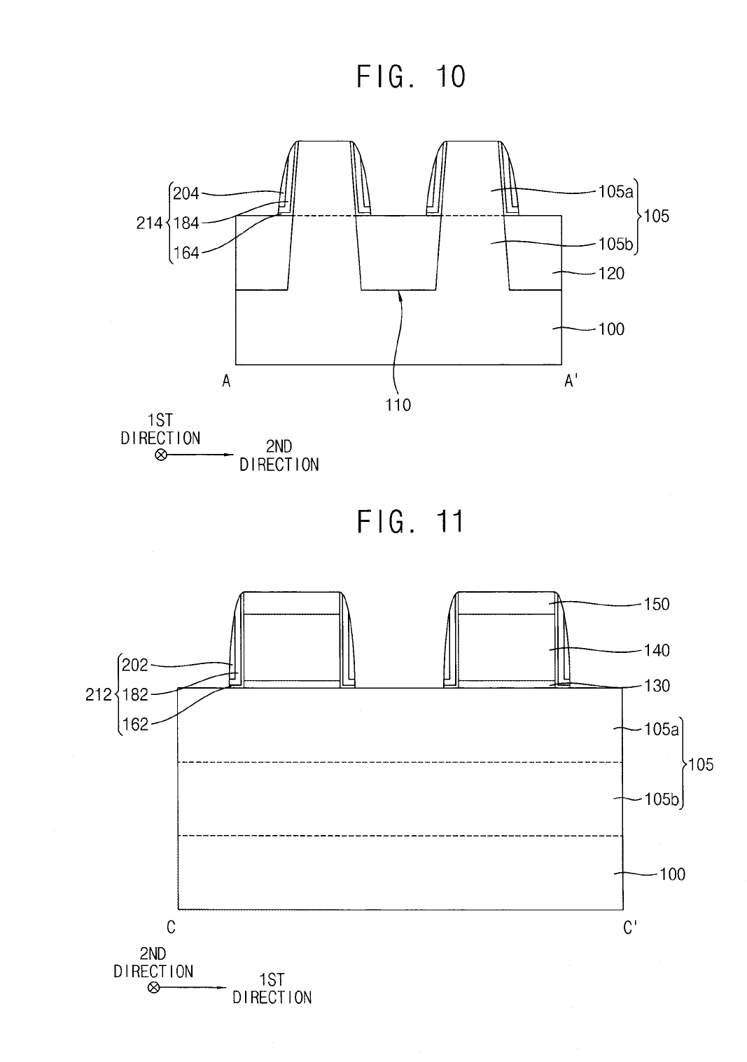

Referring to FIGS. 9 to 11, the spacer layer structure 210 may be anisotropically etched to form the gate spacer structure 212 on each of opposite sidewalls of the dummy gate structure in the first direction. A fin spacer structure 214 may be formed on each of opposite sidewalls of the upper active pattern 105a in the second direction.

The gate spacer structure 212 may include a first diffusion prevention pattern 162, a first spacer 182, and a first offset pattern 202 sequentially stacked. In example embodiments, each of the first diffusion prevention pattern 162 and the first spacer 182 may include a cross-section taken along the first direction having an L-like shape, and the first offset pattern 202 may include a cross-section taken along the first direction having a bar shape.

The fin spacer structure 214 may include a second diffusion prevention pattern 164, a second spacer 184, and a second offset pattern 204 sequentially stacked.

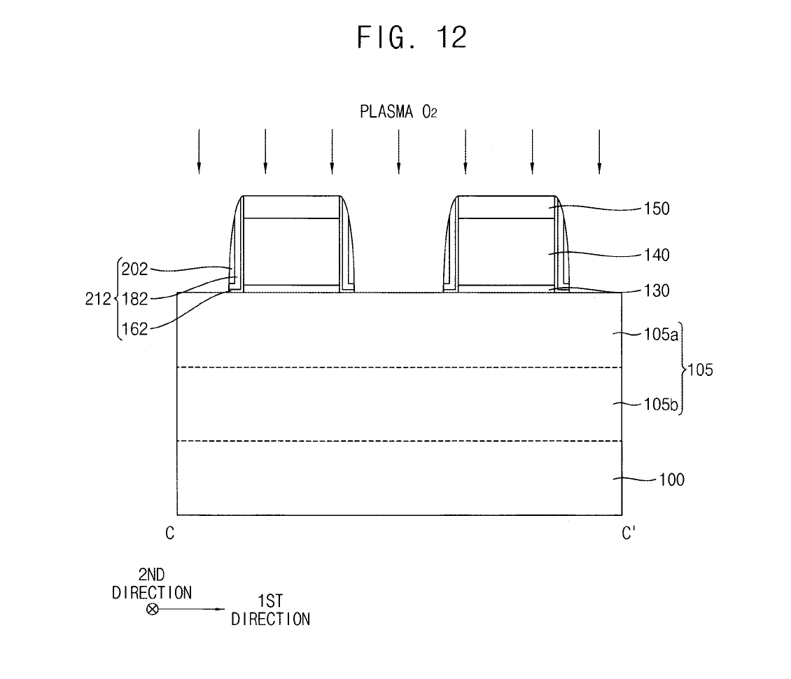

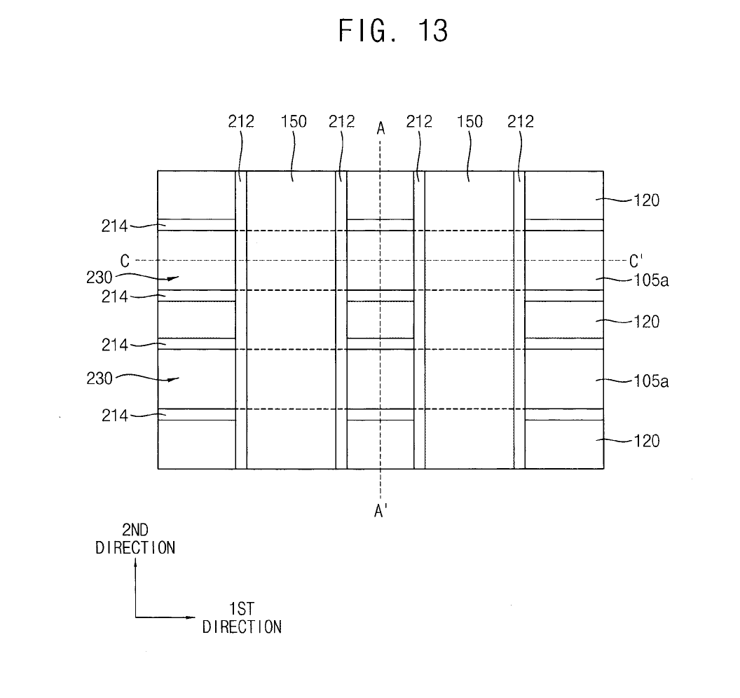

Referring to FIG. 12, a plasma treatment process may be performed on the substrate 100.

In example embodiments, the plasma treatment process may be performed using oxygen plasma, and thus the first and second offset patterns 202 and 204 including silicon oxide on the substrate 100 may be densified. Therefore, the density of the first and second offset patterns 202, 204 may be higher than non-treated offset patterns.

Referring to FIGS. 13 to 15, an upper portion of the active fin 105 adjacent the gate spacer structure 212 may be etched to form a second recess 230.

Particularly, the upper portion of the active fin 105 may be removed by a dry etching process using the dummy gate structure and the gate spacer structure 212 on a sidewall thereof as an etching mask to form the second recess 230.

When the second recess 230 is formed, the first offset pattern 202 at an outermost portion of the gate spacer structure 212 serving as the etching mask may be rarely etched. That is, the first offset pattern 202 may include silicon oxide that may be easily etched by a dry etching process. However, the first offset pattern 202 has been densified by the above-illustrated plasma treatment process. Therefore, the density of the first offset pattern 202 may be higher than a non-treated offset pattern such that the first offset pattern 202 may not be easily removed in the dry etching process.

When the second recess 230 is formed, the fin spacer structure 214 adjacent the active fin 105 may be mostly removed, and only a lower portion of the fin spacer structure 214 may remain. In example embodiments, a height of a top surface of the remaining fin spacer structure 214 may be equal to or lower than that of the active fin 105 under the second recess 230.

FIGS. 13 to 15 show that only a portion of the upper active pattern 105a is etched to form the second recess 230, so that a bottom of the second recess 230 is higher than a top surface of the lower active pattern 105b, however, example embodiments of the inventive concepts may not be limited thereto.

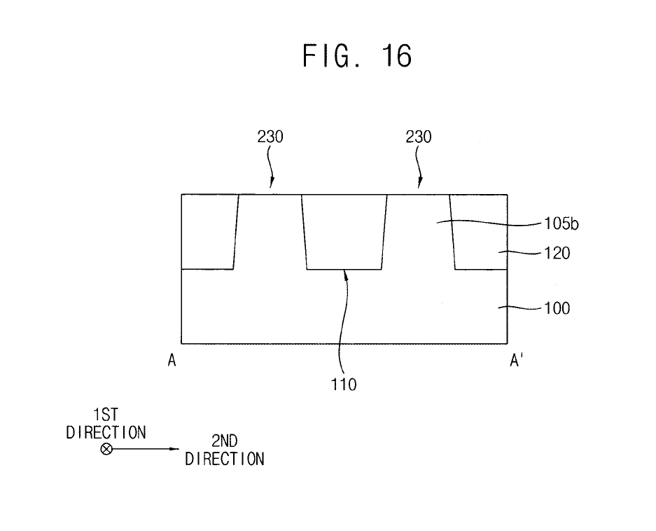

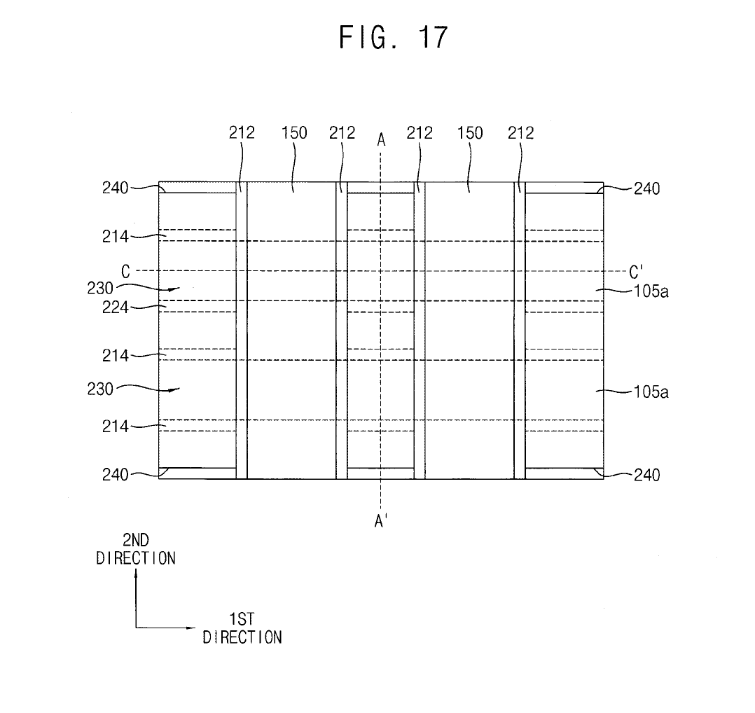

For example, referring to FIG. 16, when the second recess 230 is formed, the upper active pattern 105a may be removed so that the bottom of the second recess 230 may be substantially coplanar with the top surface of the lower active pattern 105b. In this case, the fin spacer structure 214 may be completely removed.

Alternatively, when the second recess 230 is formed, not only the upper active pattern 105a but also a portion of the lower active pattern 105b may be etched, and thus the bottom of the second recess 230 may be lower than a top surface of the lower active pattern 105b on which the second recess 230 is not formed.

In example embodiments, the etching process for forming the second recess 230 and the etching process for forming the gate spacer structure 212 and the fin spacer structure 214 may be performed in-situ.

Referring to FIGS. 17 to 19, a source/drain layer 240 may be formed in the second recess 230.

In example embodiments, the source/drain layer 240 may be formed by a selective epitaxial growth (SEG) process using an upper surface of the active fin 105 exposed by the second recess 230 as a seed.

In example embodiments, the SEG process may be formed by providing a silicon source gas, a germanium source gas, an etching gas and a carrier gas. The SEG process may be performed using e.g., silane (SiH₄) gas, disilane (Si₂H₆) gas, dichlorosilane (DCS) (SiH₂Cl₂) gas, etc., serving as the silicon source gas, e.g., germane (GeH₄) gas serving as the germanium source gas, e.g., hydrogen chloride (HCl) gas serving as the etching gas, and e.g., hydrogen (H₂) gas serving as the carrier gas. Thus, a single crystalline silicon-germanium layer may be formed to serve as the source/drain layer 240. Additionally, a p-type impurity source gas, e.g., diborane (B₂H₆) gas may be also used to form a single crystalline silicon-germanium layer doped with p-type impurities serving as the source/drain layer 240. Thus, the source/drain layer 240 may serve as a source/drain region of a positive-channel metal oxide semiconductor (PMOS) transistor.

The source/drain layer 240 may grow not only in a vertical direction but also in a horizontal direction to fill the second recess 230, and may contact a sidewall of the gate spacer structure 212. For example, when the substrate 100 is a (100) silicon substrate and the active fin 105 has a <110> crystal direction, the source/drain layer 240 may have a lowest growth rate along the <110> crystal direction, and thus the source/drain layer 240 may have a {111} crystal plane.

In example embodiments, the source/drain layer 240 may have a cross-section taken along the second direction, and the cross-section of the source/drain layer 240 may have a shape similar to a pentagon. In the shape, each of four sides except for one side contacting the upper surface of the active fin 105 may have an angle of about 54.7 degrees with respect to an upper surface of the substrate 100 or an upper surface of the isolation pattern 120.

In example embodiments, when the active fins 105 disposed in the second direction are close to each other, the source/drain layers 240 growing on the respective active fins 105 may be merged with each other. FIGS. 17 to 19 show that two source/drain layers 240 grown on neighboring two active fins 105 are merged with each other, however, example embodiments of the inventive concepts may not be limited thereto. Thus, more than two source/drain layers 240 may be merged with each other.

Up to now, the source/drain layer 240 serving as the source/drain region of the PMOS transistor have been illustrated, however, example embodiments of the inventive concepts may not be limited thereto, and the source/drain layer 240 may also serve as a source/drain region of a negative-channel metal oxide semiconductor (NMOS) transistor.

Particularly, the SEG process may be formed using a silicon source gas, a carbon source gas, an etching gas and a carrier gas, and thus a single crystalline silicon carbide layer may be formed as the source/drain layer 240. In the SEG process, e.g., silane (SiH₄) gas, disilane (Si₂H₆) gas, dichlorosilane (SiH₂Cl₂) gas, etc., may be used as the silicon source gas, e.g., monomethylsilane (SiH₃CH₃) gas may be used as the carbon source gas, e.g., hydrogen chloride (HCl) gas may be used as the etching gas, and e.g., hydrogen (H₂) gas may be used as the carrier gas. Additionally, an n-type impurity source gas, e.g., phosphine (PH₃) gas may be also used to form a single crystalline silicon carbide layer doped with n-type impurities.

Alternatively, the SEG process may be performed using a silicon source gas, an etching gas and a carrier gas, and thus a single crystalline silicon layer may be formed as the source/drain layer 240. In the SEG process, an n-type impurity source gas, e.g., phosphine (PH₃) gas may be also used to form a single crystalline silicon layer doped with n-type impurities.

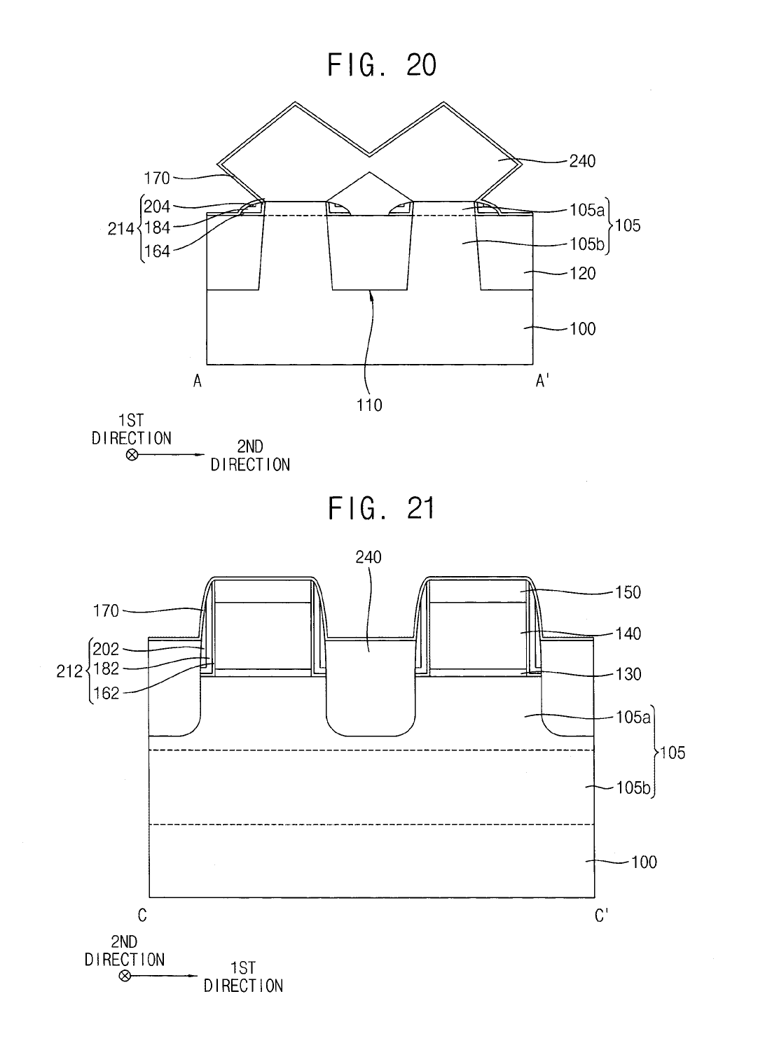

Referring to FIGS. 20 and 21, an etch stop layer 170 may be formed on the dummy gate structure, the gate spacer structure 212, the fin spacer structure 214, the source/drain layer 240 and the isolation pattern 120.

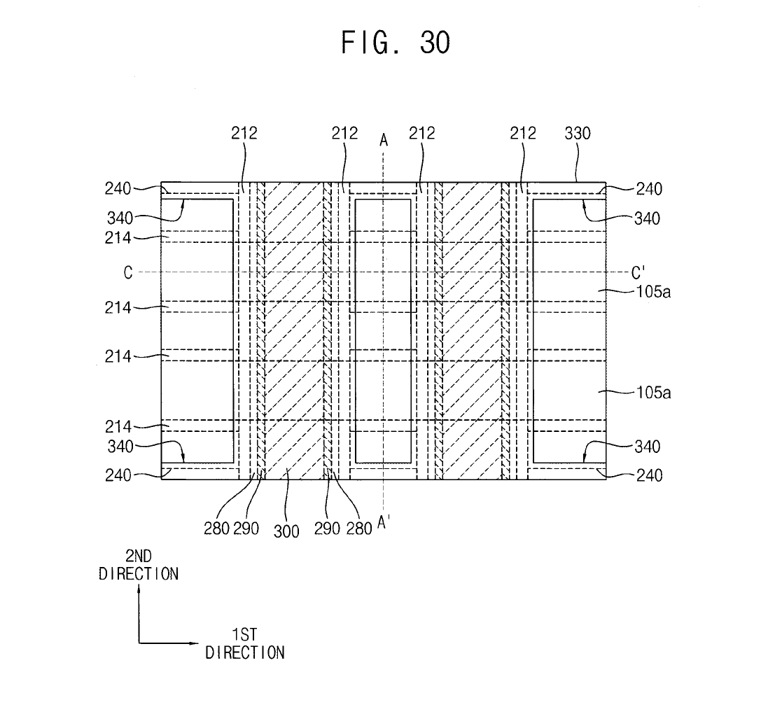

In example embodiments, the etch stop layer 170 may be formed of a nitride, e.g., silicon nitride. The etch stop layer 170 may prevent the source/drain layer 240 from being etched in a subsequent process for forming a contact hole 340 (refer to FIGS. 30 to 32).

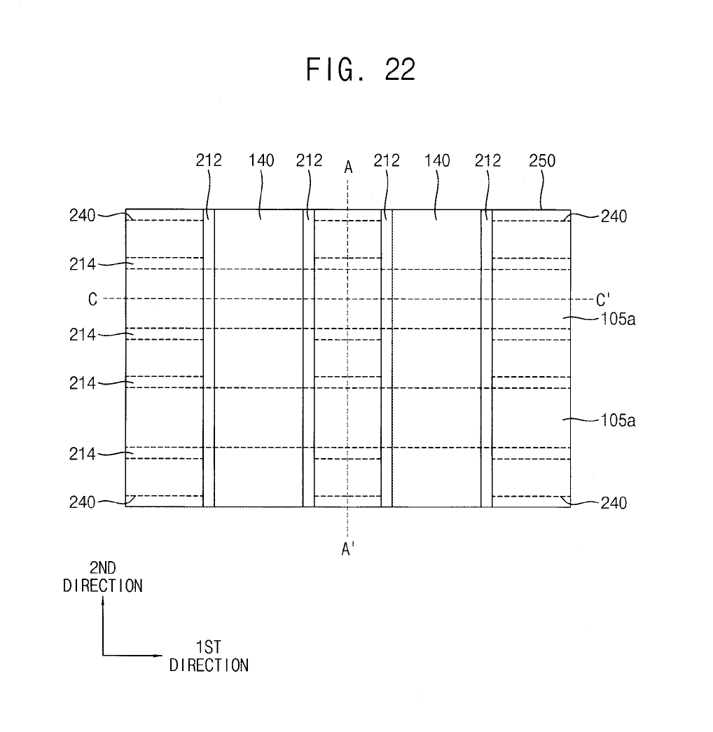

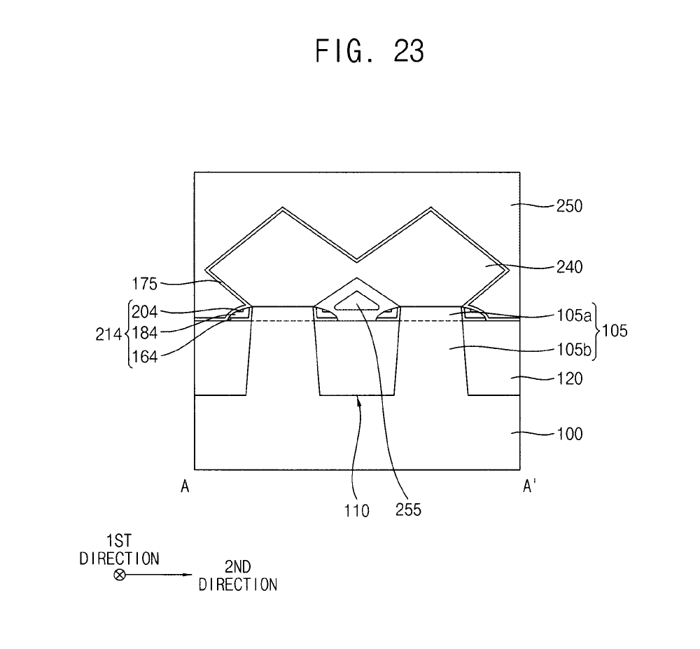

Referring to FIGS. 22 to 24, an insulation layer 250 may be formed on the etch stop layer 170 to a sufficient height, and the insulation layer 250 and the etch stop layer 170 may be planarized until an upper surface of the dummy gate electrode 140 of the dummy gate structure may be exposed.

In the planarization process, the dummy gate mask 150 may be removed, and a portion of the etch stop layer 170 on an upper surface of the dummy gate mask 150 may be removed to form an etch stop pattern 175. Thus, the etch stop pattern 175 may be formed on an upper sidewall of the gate spacer structure 212, a sidewall of the fin spacer structure 214, and an upper surface of the source/drain layer 240. That is, the etch stop pattern 175 may include a cross-section taken along the first direction having an L-like shape.

A space between the merged source/drain layers 240 and the isolation pattern 120 may not be filled with the insulation layer 250, and thus an air gap 255 may be formed.

The insulation layer 250 may be formed of silicon oxide, or tonen silazene (TOSZ). The planarization process may be performed by a chemical mechanical polishing (CMP) process and/or an etch back process.

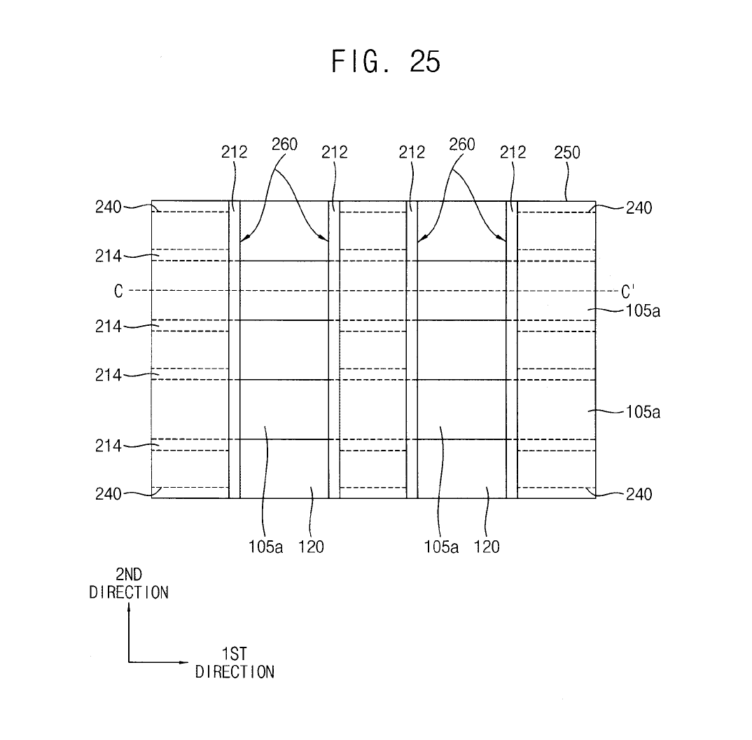

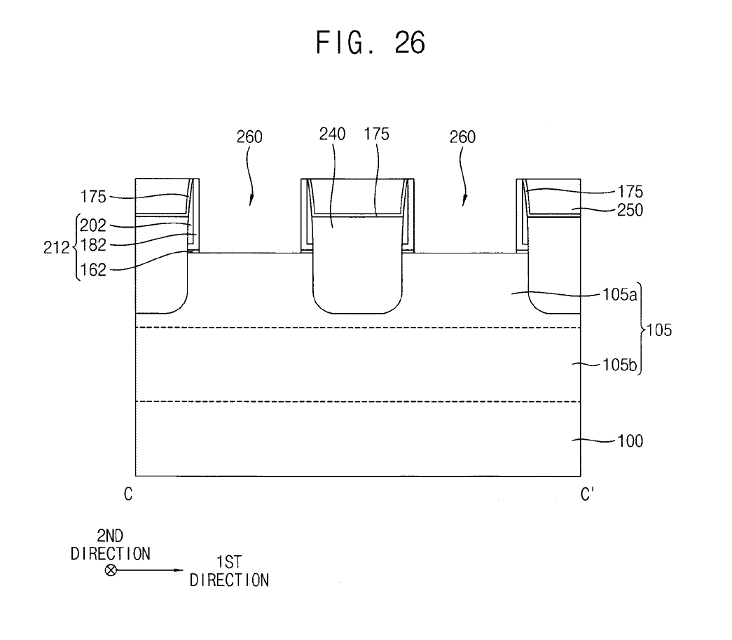

Referring to FIGS. 25 and 26, the exposed dummy gate electrode 140 and the dummy gate insulation pattern 130 thereunder may be removed to form an opening 260 exposing an inner sidewall of the gate spacer structure 212 and an upper surface of the active fin 105.

In example embodiments, the dummy gate electrode 140 and the dummy gate insulation pattern 130 may be removed by a dry etching process or a wet etching process.

The wet etching process may be performed using, e.g., hydrofluoric acid (HF), and the first diffusion prevention pattern 162 may be partially removed to expose the first spacer 182. However, the first spacer 182 may not be easily removed by the wet etching process, and thus may remain. Accordingly, a remaining portion of the gate spacer structure 212 may not be damaged.

A portion of the first diffusion prevention pattern 162 on a sidewall of the first spacer 182 may be mostly removed, however, a portion of the first diffusion prevention pattern 162 on the upper surface of the active fin 105 may not completely removed but at least partially remain. Thus, the source/drain layer 240 adjacent the first diffusion prevention pattern 162 may not be exposed by the opening 260.

FIG. 26 shows that the first diffusion prevention pattern 162 is partially removed so that a sidewall of the remaining first diffusion prevention pattern 162 may be aligned with an extension plane of the sidewall of the first spacer 182, and thus an upper surface of the first diffusion prevention pattern 162 may have an area substantially equal to a bottom of the first spacer 182.

However, example embodiments of the inventive concepts may not be limited thereto, and an upper surface of the first diffusion prevention pattern 162 may have an area less than the bottom of the first spacer 182.

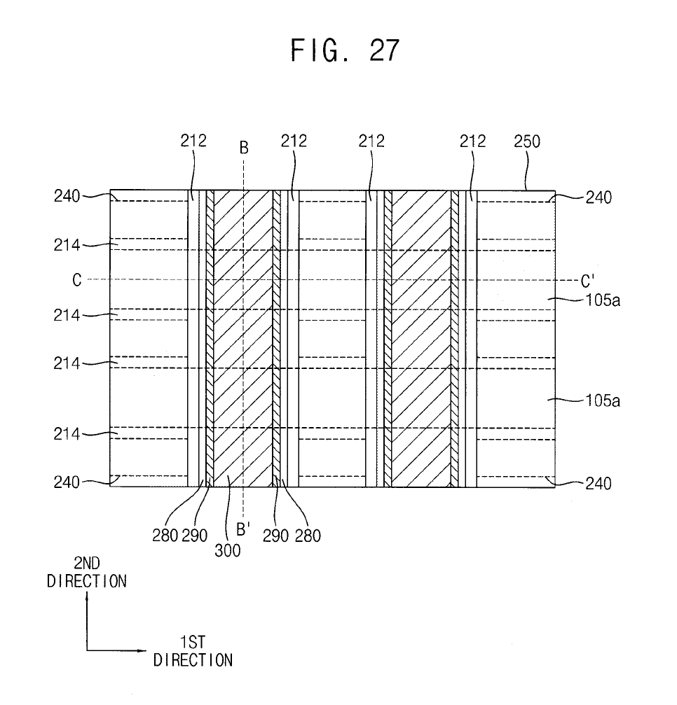

Referring to FIGS. 27 to 29, a gate structure 310 may be formed to fill the opening 260.

Particularly, after performing a thermal oxidation process on the upper surface of the active fin 105 exposed by the opening 260 to form an interface pattern 270, a gate insulation layer and a work function control layer may be sequentially formed on the interface pattern 270, the isolation pattern 120, the gate spacer structure 212, and the insulation layer 250, and a gate electrode layer may be formed on the work function control layer to sufficiently fill a remaining portion of the opening 260.

The gate insulation layer may be formed of a metal oxide having a high dielectric constant, e.g., hafnium oxide, tantalum oxide, zirconium oxide, or the like, by a CVD process or an ALD process. The work function control layer may be formed of a metal nitride or a metal alloy, e.g., titanium nitride, titanium aluminum, titanium aluminum nitride, tantalum nitride, tantalum aluminum nitride, etc., and the gate electrode layer may be formed of a material having a low resistance, e.g., a metal such as aluminum, copper, tantalum, etc., or a metal nitride thereof. The work function control layer and the gate electrode layer may be formed by an ALD process, a physical vapor deposition (PVD) process, or the like. In an example embodiment, a heat treatment process, e.g., a rapid thermal annealing (RTA) process, a spike rapid thermal annealing (spike RTA) process, a flash rapid thermal annealing (flash RTA) process or a laser annealing process may be further performed.

The interface pattern 270 may be formed instead of the thermal oxidation process, by a CVD process, an ALD process, or the like, similarly to the gate insulation layer or the gate electrode layer. In this case, the interface pattern 270 may be formed not only on the upper surface of the active fin 105 but also on the upper surface of the isolation pattern 120 and the inner sidewall of the gate spacer structure 212.

The gate electrode layer, the work function control layer, and the gate insulation layer may be planarized until an upper surface of the insulation layer 250 may be exposed to form a gate insulation pattern 280 and a work function control pattern 290 sequentially stacked on the interface pattern 270, the isolation pattern 120, and the inner sidewall of the gate spacer structure 212, and a gate electrode 300 filling the remaining portion of the opening 260 on the work function control pattern 290.

Accordingly, a lower surface and a sidewall of the gate electrode 300 may be covered by the work function control pattern 290. In example embodiments, the planarization process may be performed by a CMP process and/or an etch back process.

The interface pattern 270, the gate insulation pattern 280, the work function control pattern 290 and the gate electrode 300 sequentially stacked may form the gate structure 310, and the gate structure 310 together with the source/drain layer 240 may form a PMOS transistor or an NMOS transistor according to the conductivity type of the source/drain layer 240.

Referring to FIGS. 30 to 32, a capping layer 320 and an insulating interlayer 330 may be sequentially formed on the insulation layer 250, the gate structure 310, and the gate spacer structure 212, and a contact hole 340 may be formed through the insulation layer 250, the capping layer 320 and the insulating interlayer 330 to expose an upper surface of the source/drain layer 240.

The capping layer 320 may be formed of a nitride, e.g., silicon nitride, silicon oxynitride, silicon carbonitride, silicon oxycarbonitride, etc., and the insulating interlayer 330 may be formed of silicon oxide, e.g., tetra ethyl ortho silicate (TEOS).

In example embodiments, the contact hole 340 may be formed to expose only a portion of the upper surface of the source/drain layer 240 in the first direction. Thus, the etch stop pattern 175 may partially remain on the upper surface of the source/drain layer 240.

However, example embodiments of the inventive concepts may not be limited thereto, and the contact hole 340 may be self-aligned with the gate spacer structure 212. Thus, the contact hole 340 may expose an entire portion of the upper surface of the source/drain layer 240 in the first direction, and the etch stop pattern 175 on the upper surface of the source/drain layer 240 may be mostly removed.

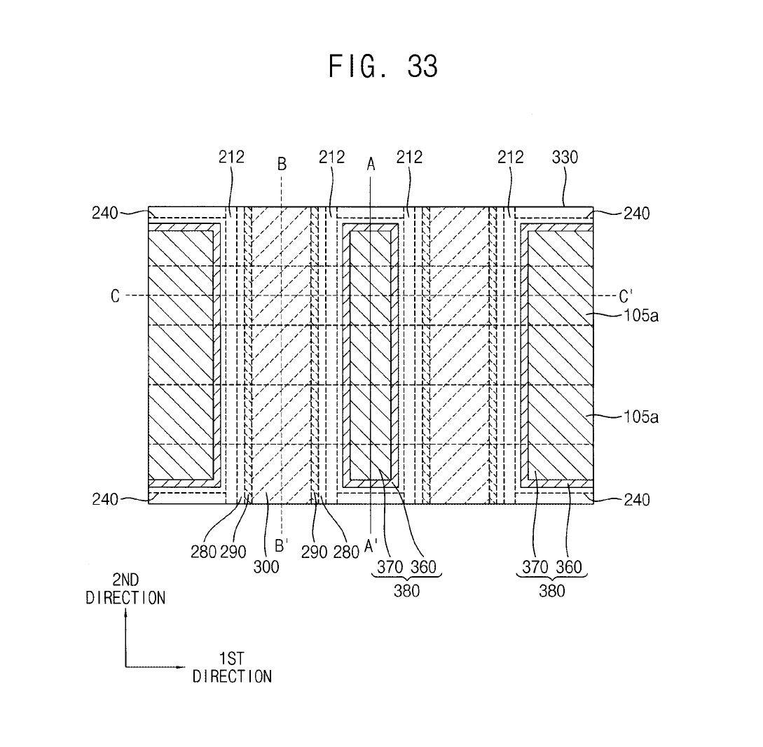

Referring to FIGS. 33 to 36, after forming a first metal layer on the exposed upper surface of the source/drain layer 240, a sidewall of the contact hole 340, and the upper surface of the insulating interlayer 330, a heat treatment process may be performed thereon to form a metal silicide pattern 350 on the source/drain layer 240. An unreacted portion of the first metal layer may be removed.

The first metal layer may be formed of a metal, e.g., titanium, cobalt, nickel, etc.

A barrier layer may be formed on the metal silicide pattern 350, the sidewall of the contact hole 340 and the upper surface of the insulating interlayer 330, a second metal layer may be formed on the barrier layer to fill the contact hole 340, and the second metal layer and the barrier layer may be planarized until the upper surface of the insulating interlayer 330 may be exposed.

Thus, a contact plug 380 may be formed on the metal silicide pattern 350 to fill the contact hole 340.

The barrier layer may be formed of a metal nitride, e.g., titanium nitride, tantalum nitride, tungsten nitride, etc., and the second metal layer may be formed of a metal, e.g., tungsten, copper, etc.

The contact plug 380 may include a metal pattern 370 and a barrier pattern 360 covering a lower surface and a sidewall thereof.

A wiring (not shown) and a via (not shown) may be further formed to be electrically connected to the contact plug 380 to complete the semiconductor device.

As illustrated above, the plasma treatment process may be performed such that the first offset pattern 202 included in the gate spacer structure 212 may not be removed in the dry etching process for forming the second recess 230.

However, example embodiments of the inventive concepts may not be limited thereto, and for example, the offset layer 200 may be formed to have a thick thickness so as to remain after the dry etching process. For example, the spacer layer 180, the offset layer 200 and the etch stop layer 170 may be formed to have thicknesses of about 4-8 nm, 4-8 nm and 2-4 nm, respectively, and the first spacer 182, the first offset pattern 202 and the etch stop pattern 175 in the final semiconductor device may have thicknesses of about 4-8 nm, 2-4 nm and 2-4 nm, respectively. In an example embodiment, the first offset pattern 202 may be equal to or more than that of the etch stop pattern 175.

In the semiconductor device manufactured by the above processes, the gate spacer structure 212 on the sidewall of the gate structure 310 may include the first diffusion prevention pattern 162, the first spacer 182 and the first offset pattern 202 sequentially stacked on the active fin 105.

In example embodiments, the first diffusion prevention pattern 162 may have a thin plate shape contacting a lower sidewall of the gate structure 310. That is, the first diffusion prevention pattern 162 may include a cross-section taken along the first direction having a bar shape. In example embodiments, the first spacer 182 may be formed on an upper surface of the first diffusion prevention pattern 162 and contact most portion of the sidewall of the gate structure 310. The first spacer 182 may include a cross-section taken along the first direction having an L-like shape. In example embodiments, the first offset pattern 202 may be formed on the first spacer 182, and may include a cross-section taken along the first direction having a bar shape.

In example embodiments, the gate spacer structure 212 may include the first offset pattern 202 containing silicon oxide having a dielectric constant less than that of silicon nitride or silicon oxycarbonitride, and having a band gap more than that of silicon nitride or silicon oxycarbonitride. Thus, a leakage current through the gate spacer structure 212 may be reduced, and a parasitic capacitance between neighboring gate structures 310 may be reduced. Accordingly, the semiconductor device including the gate spacer structure 212 may have good electrical characteristics.

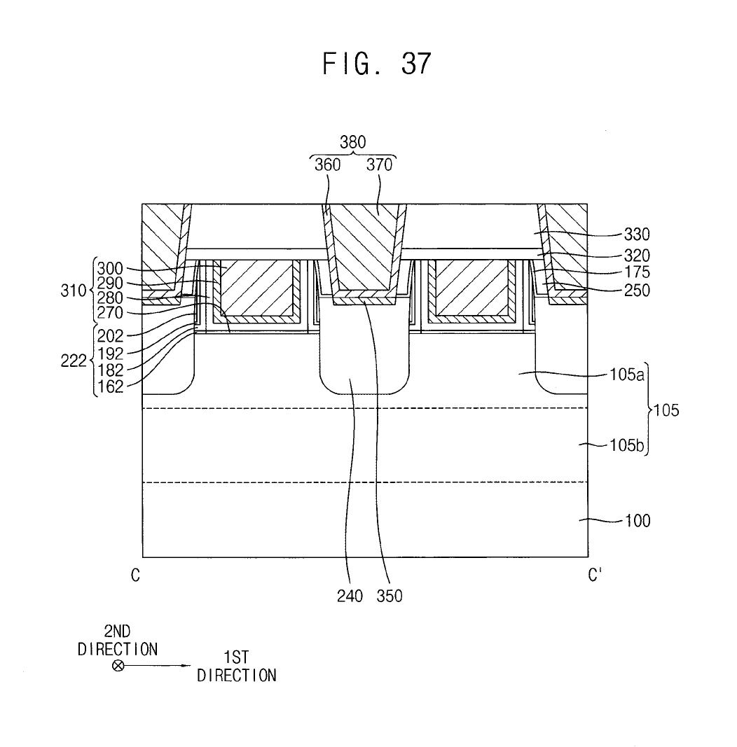

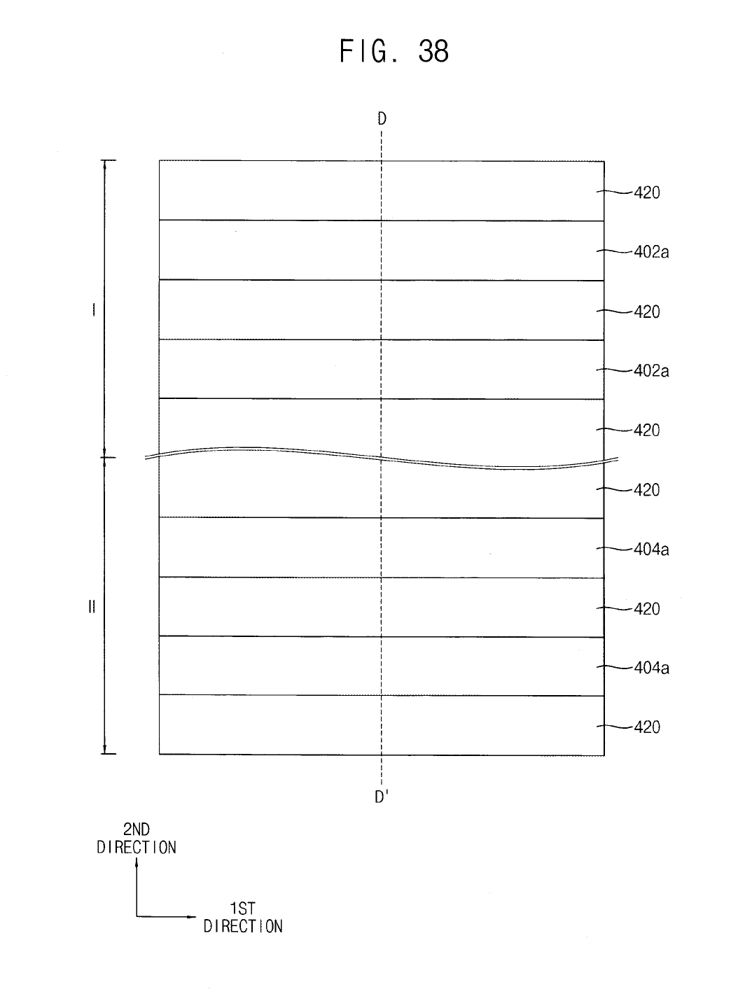

FIG. 37 is a cross-sectional view illustrating a semiconductor device in accordance with example embodiments. The semiconductor device may be substantially the same as or similar to that of FIGS. 33 to 36, except for the gate spacer structure. Thus, like reference numerals refer to like elements, and detailed descriptions thereon are omitted herein.

Referring to FIG. 37, a gate spacer structure 222 may further include a first outgassing prevention pattern 192 between the first spacer 182 and the first offset pattern 202.

In example embodiments, the first outgassing prevention pattern 192 may include silicon nitride, and may include a cross-section taken along the first direction having an L-like shape.

When the source/drain layer 240 is formed by the SEG process, the first outgassing prevention pattern 192 may prevent carbon in the first spacer 182 of the gate spacer structure 212 from outgassing therefrom, so that no facet may be formed in the source/drain layer 240.

The fin spacer structure of the semiconductor device may further include a second outgassing prevention pattern (not shown) between the second spacer 184 and the second offset pattern 204.

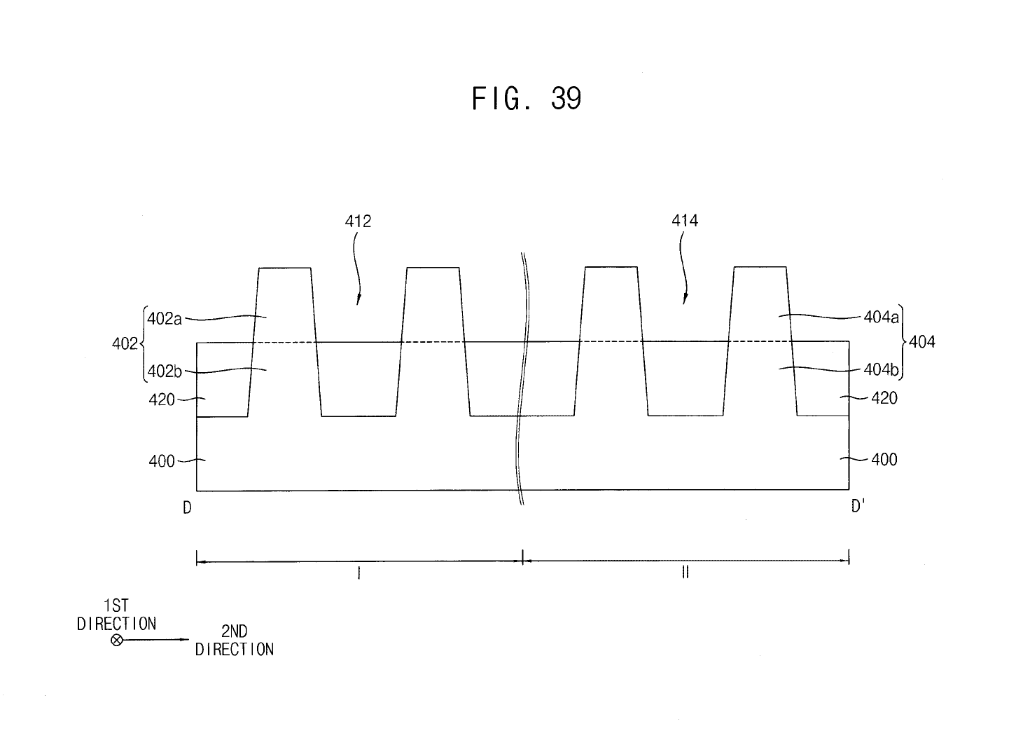

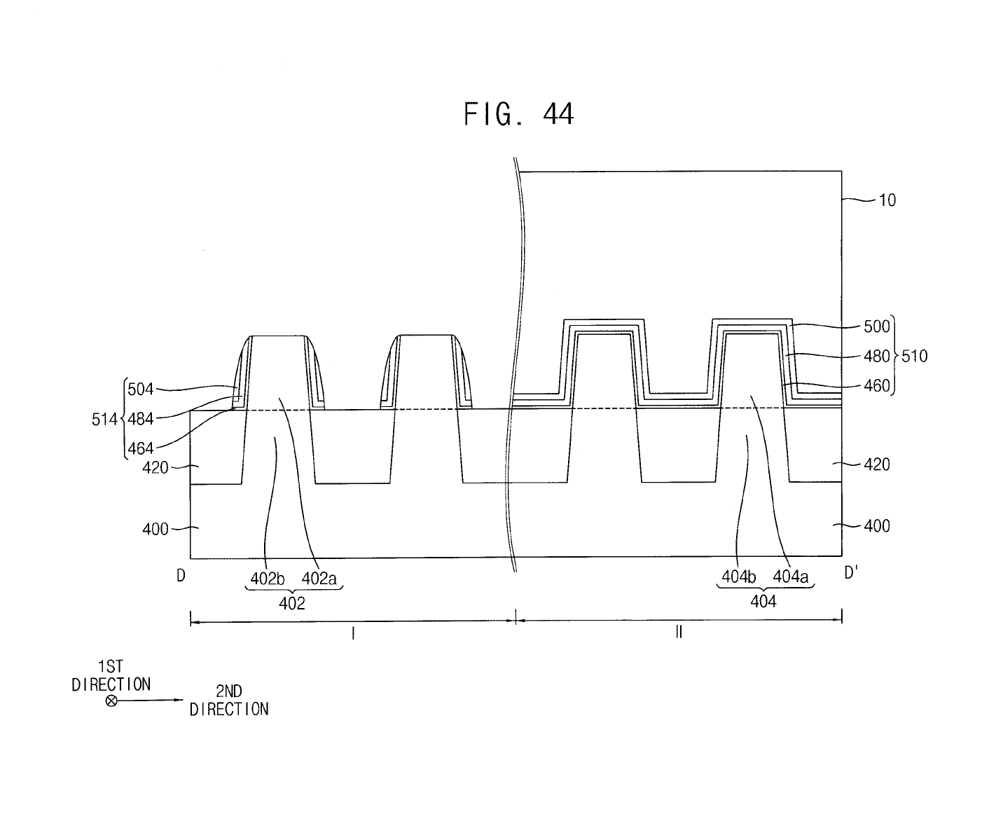

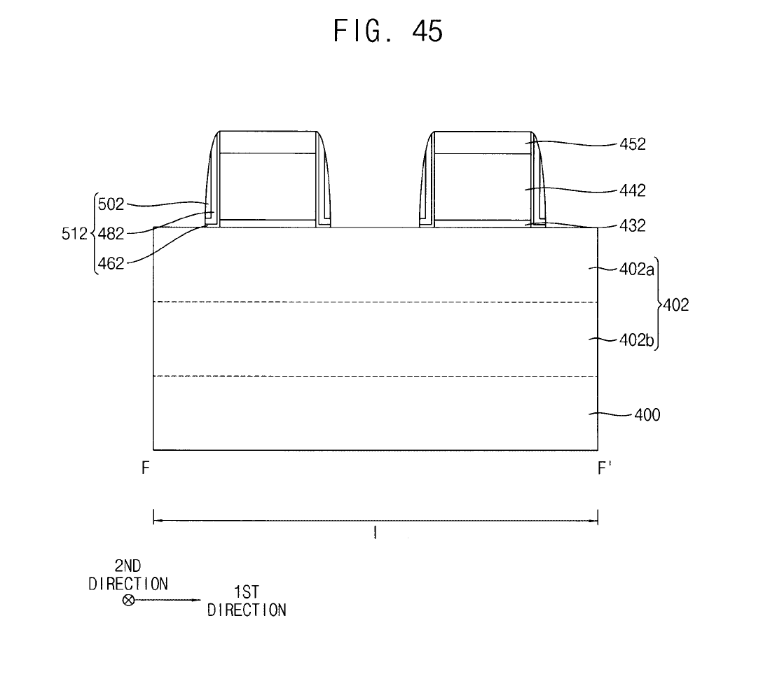

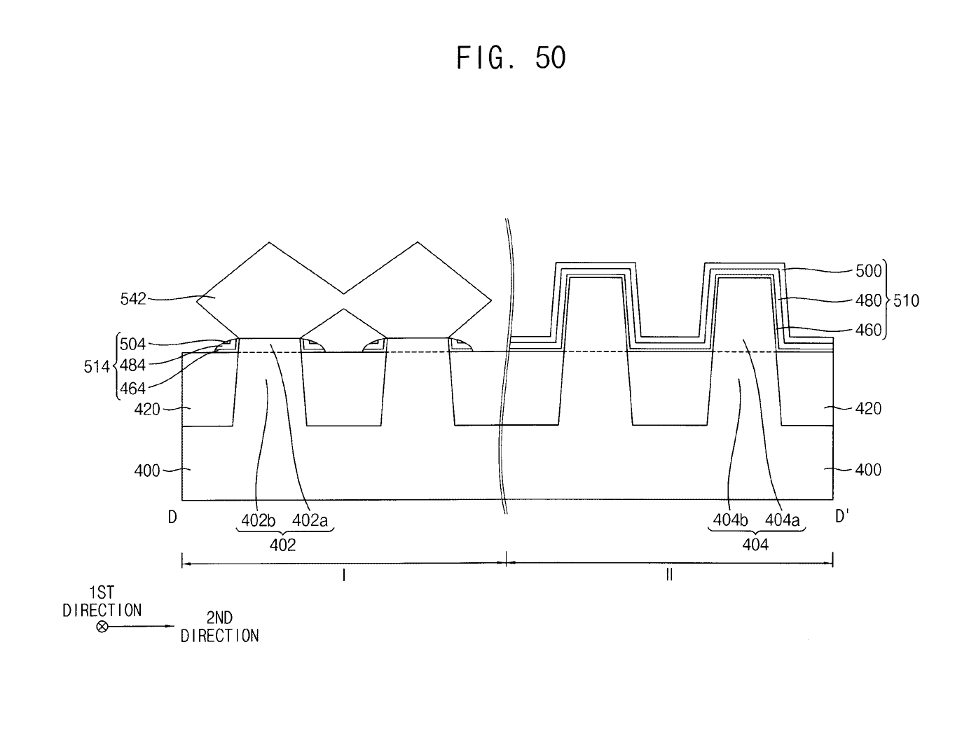

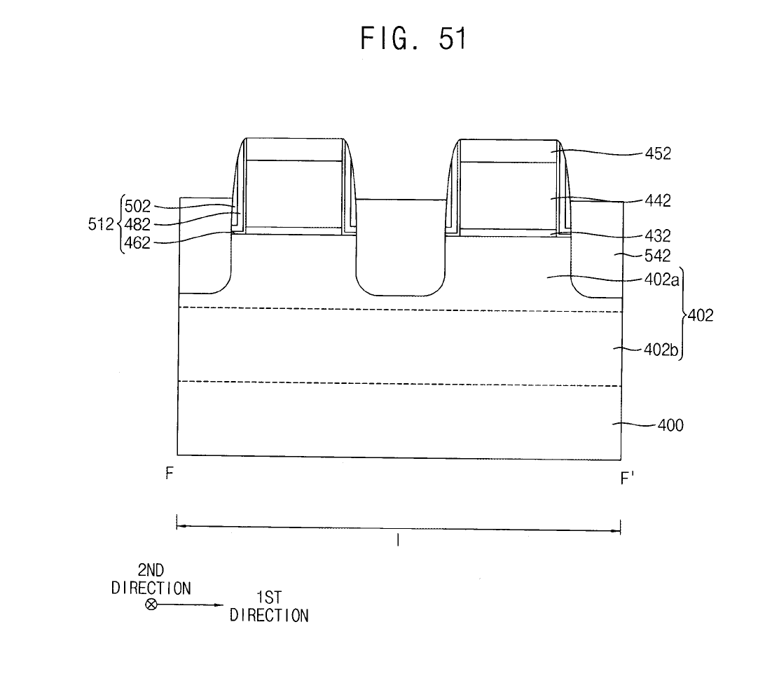

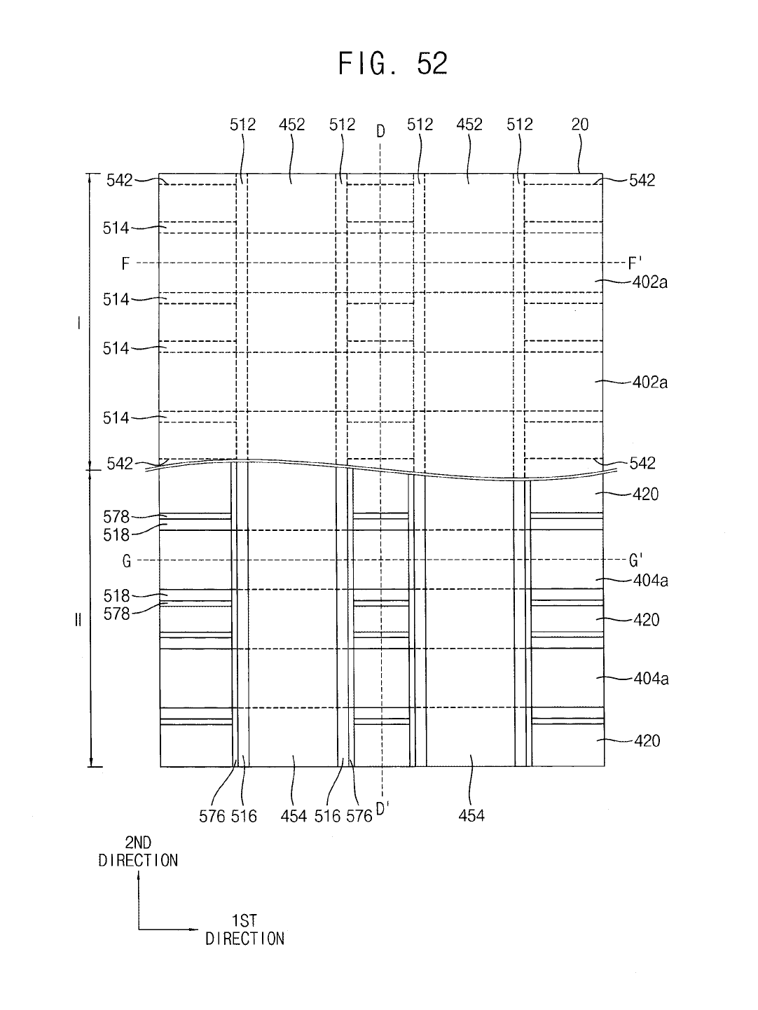

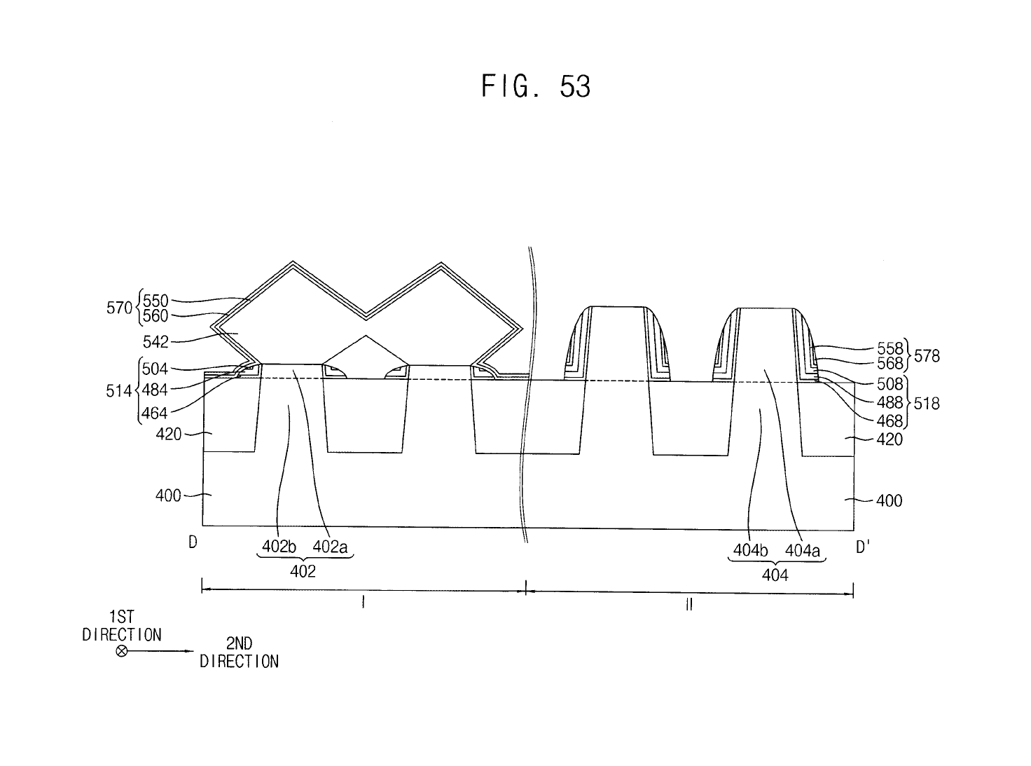

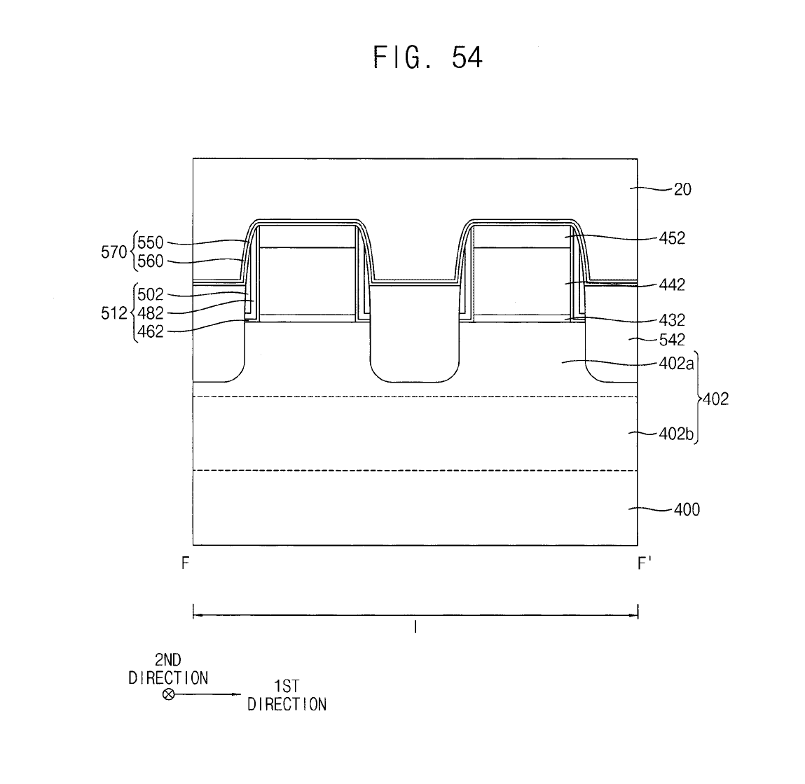

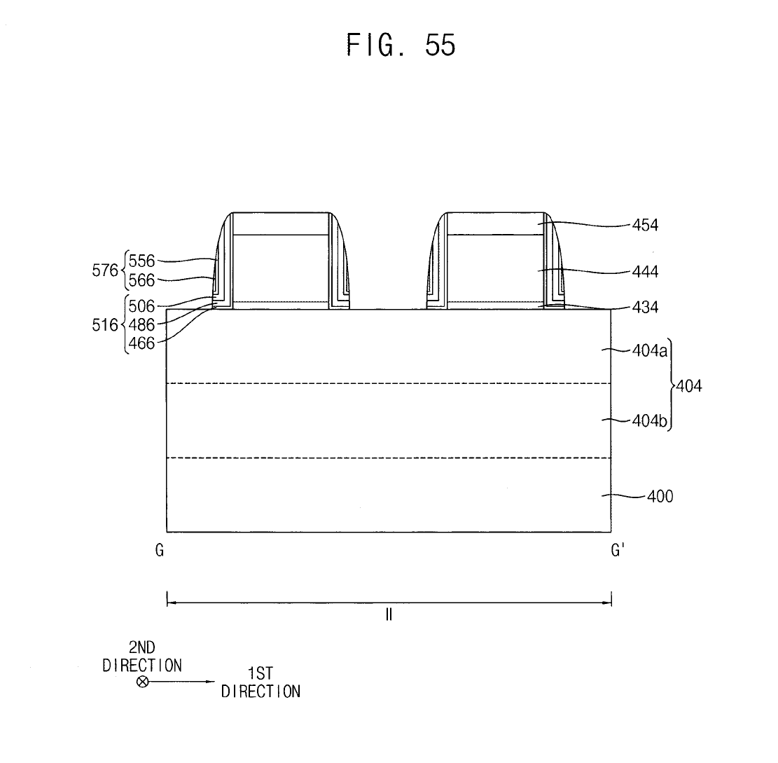

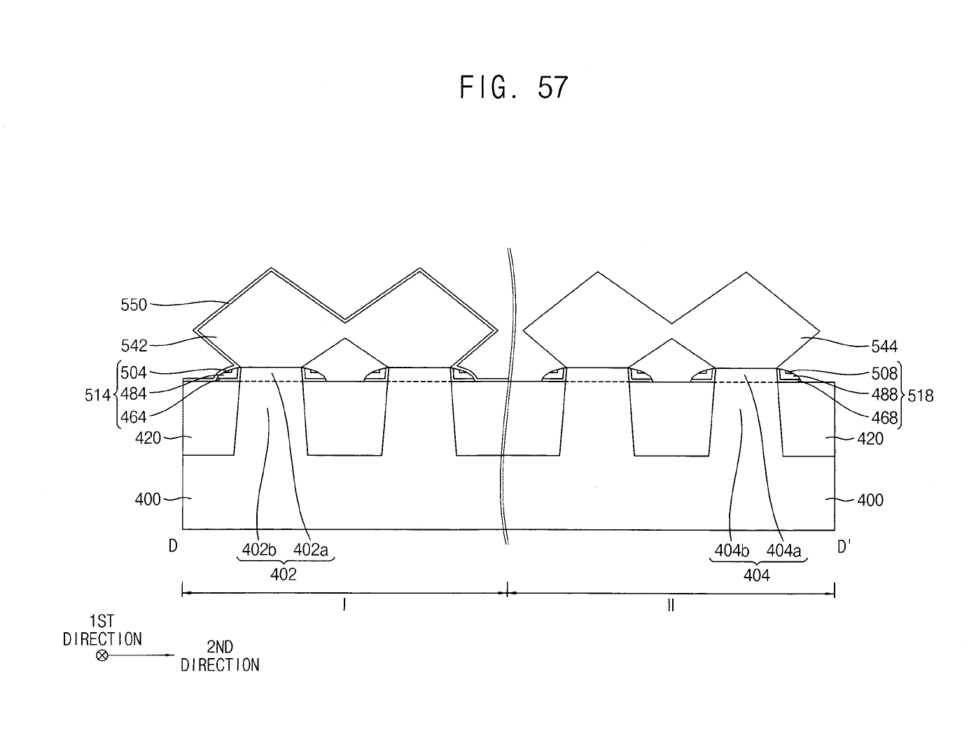

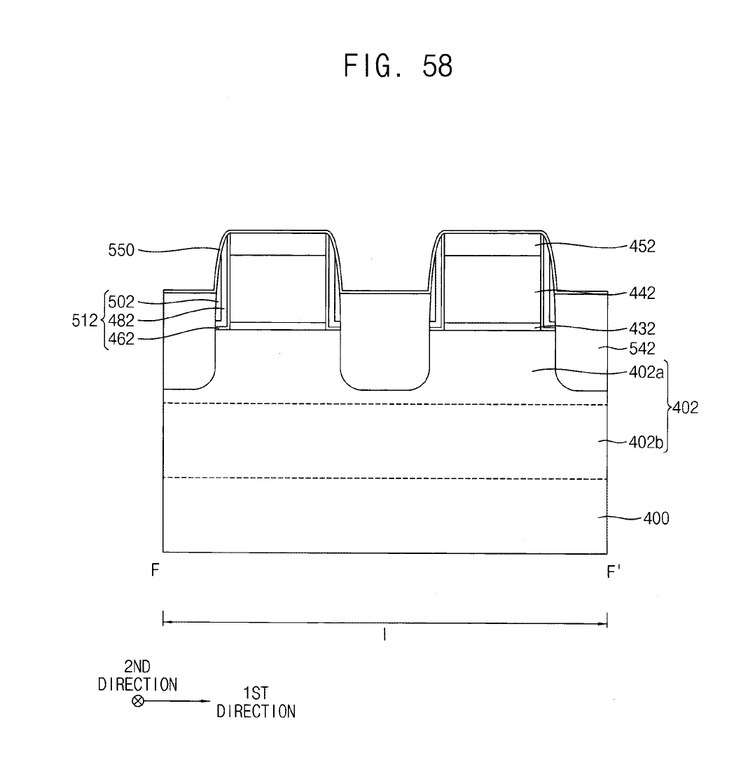

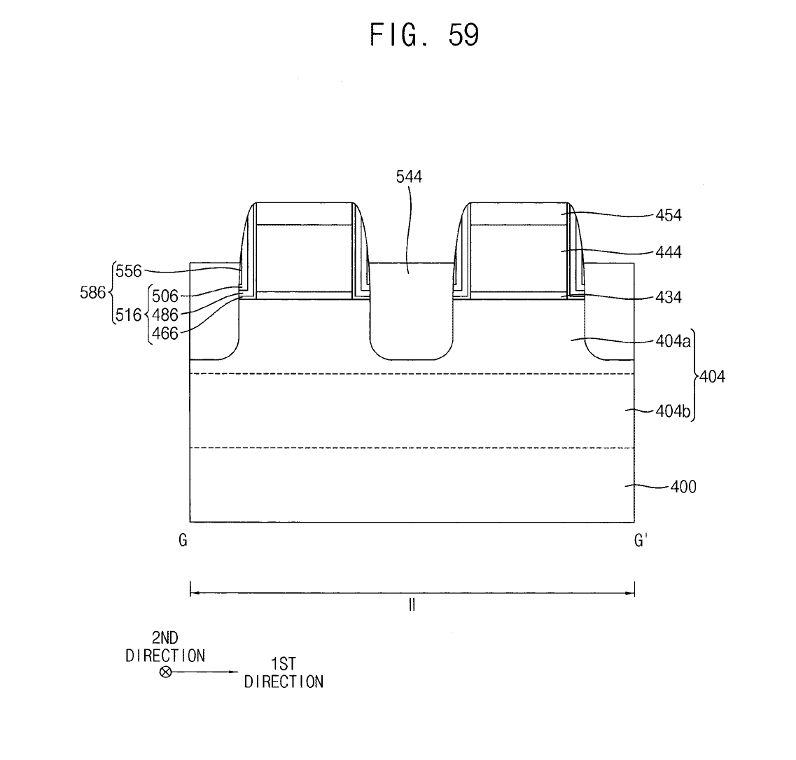

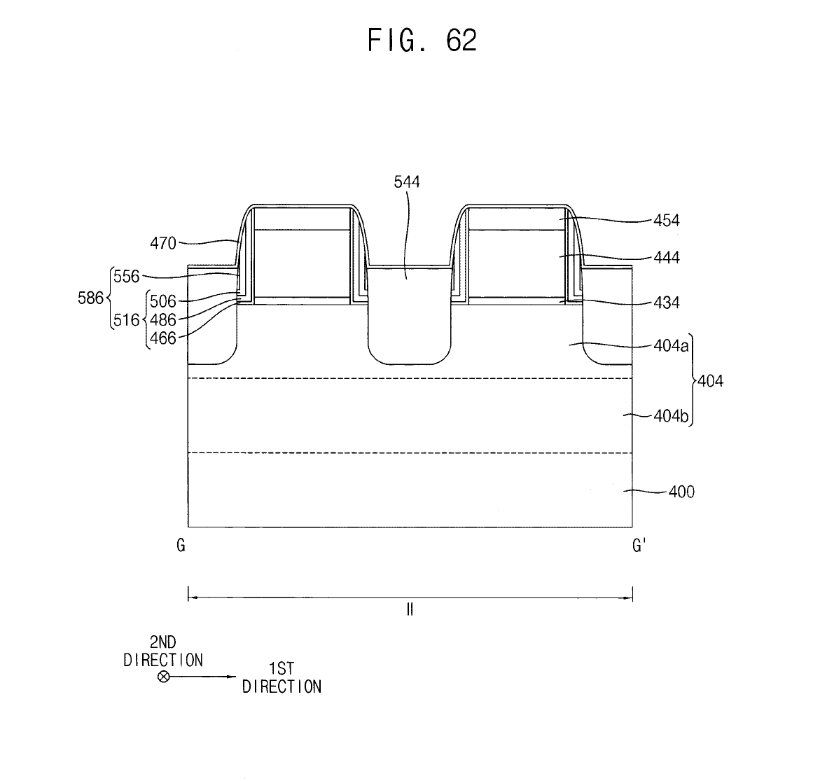

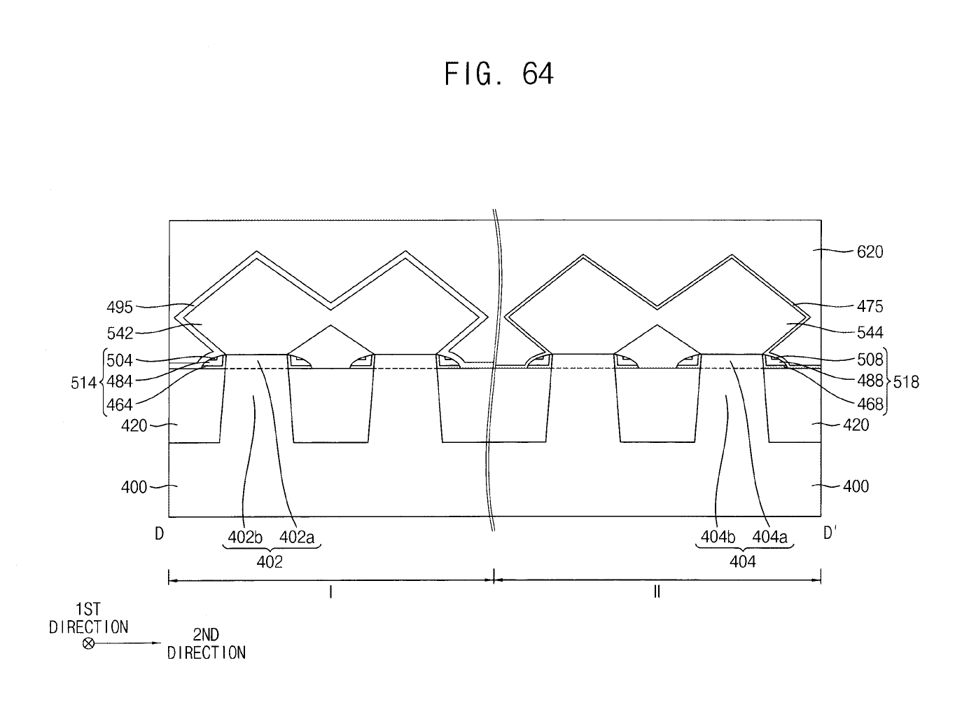

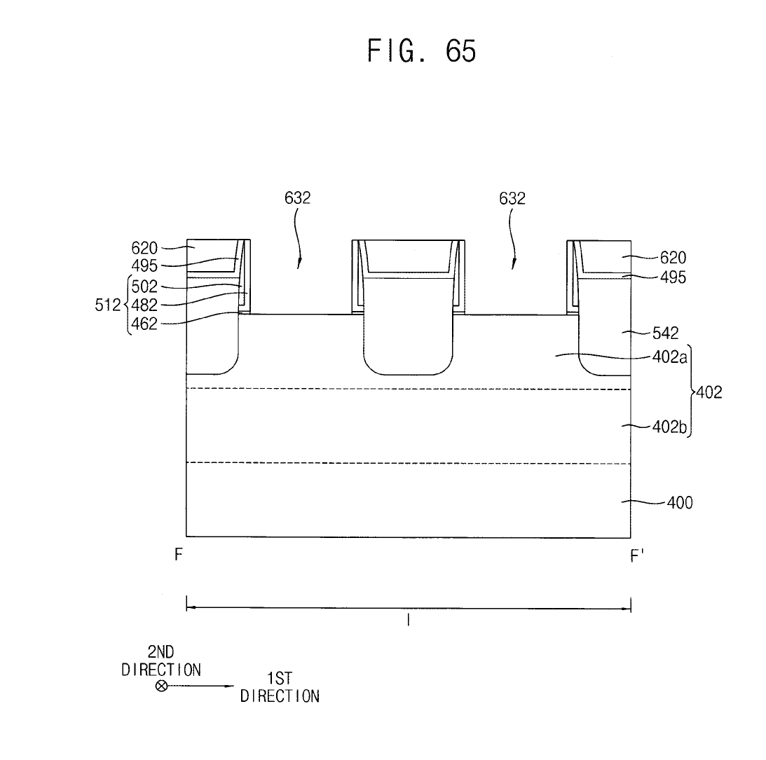

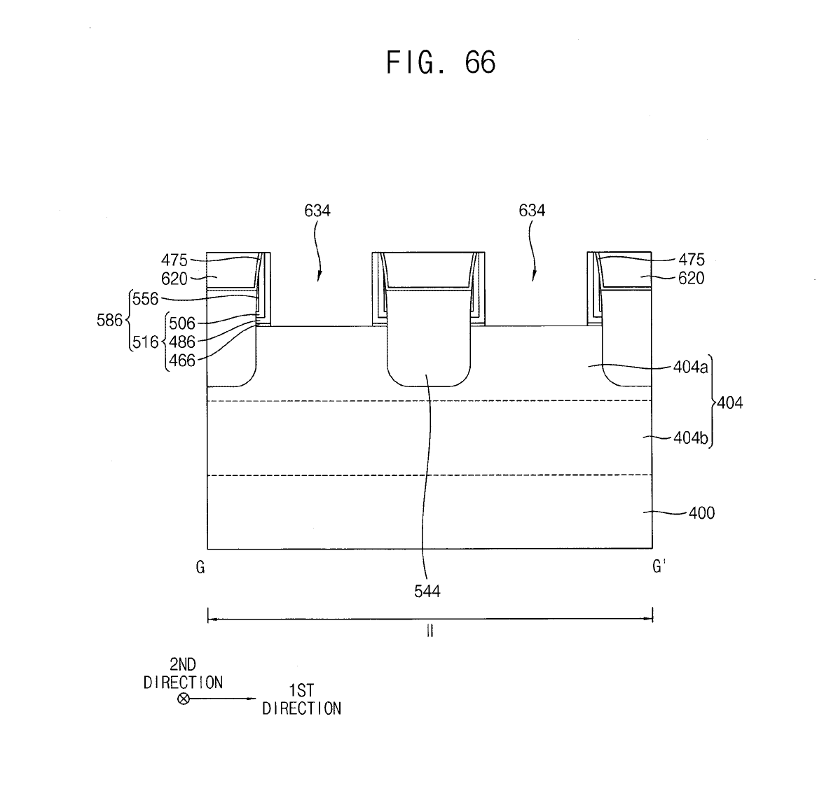

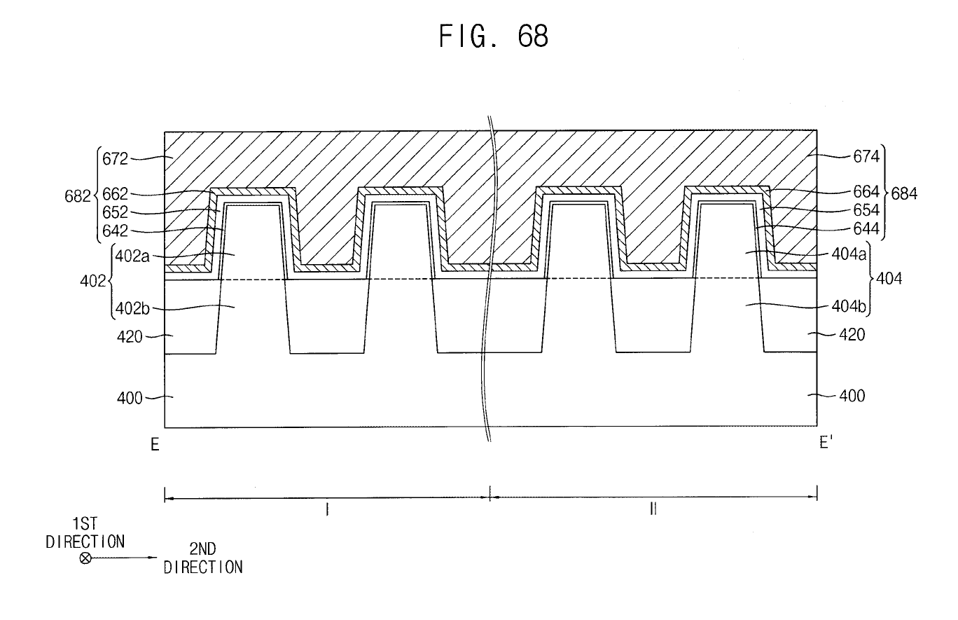

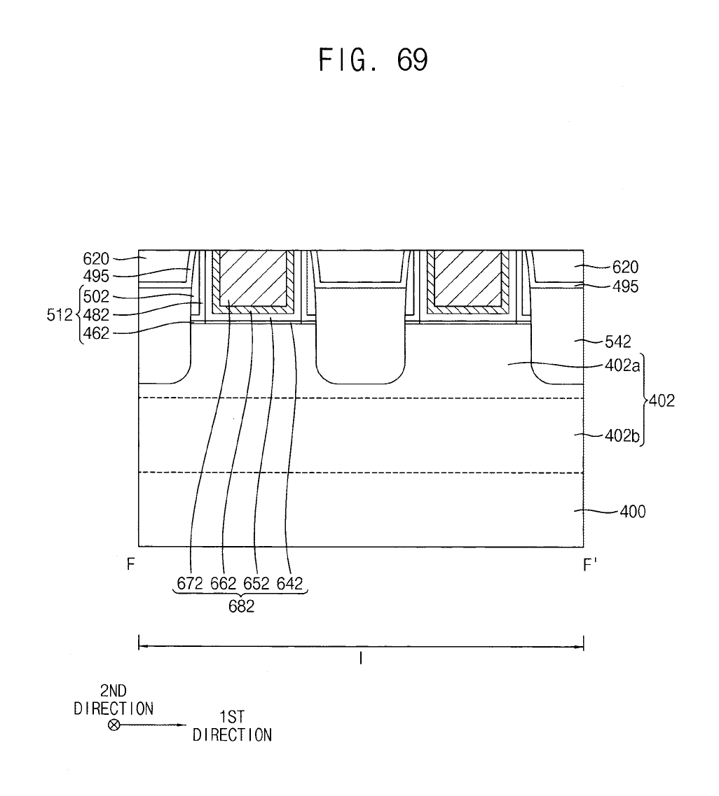

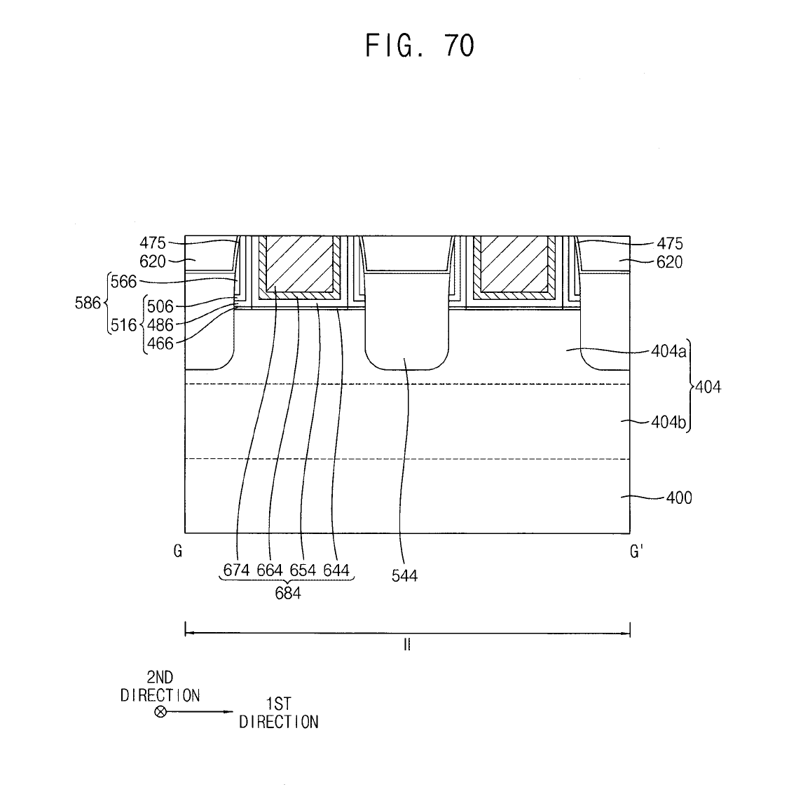

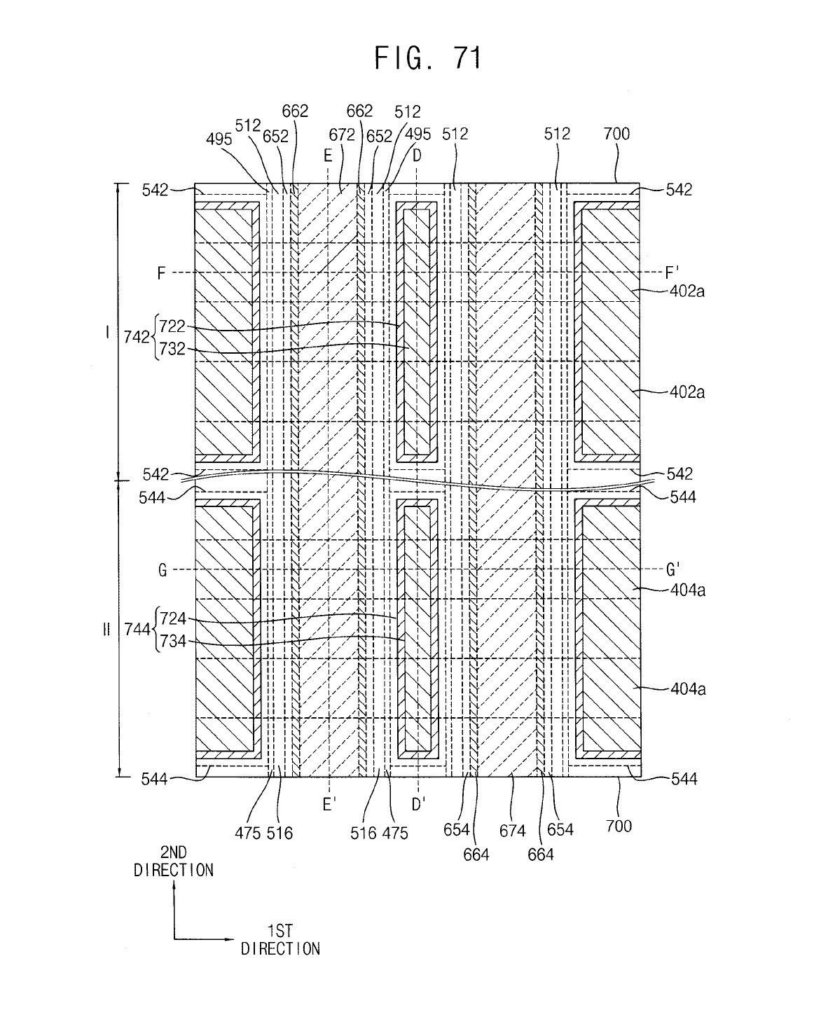

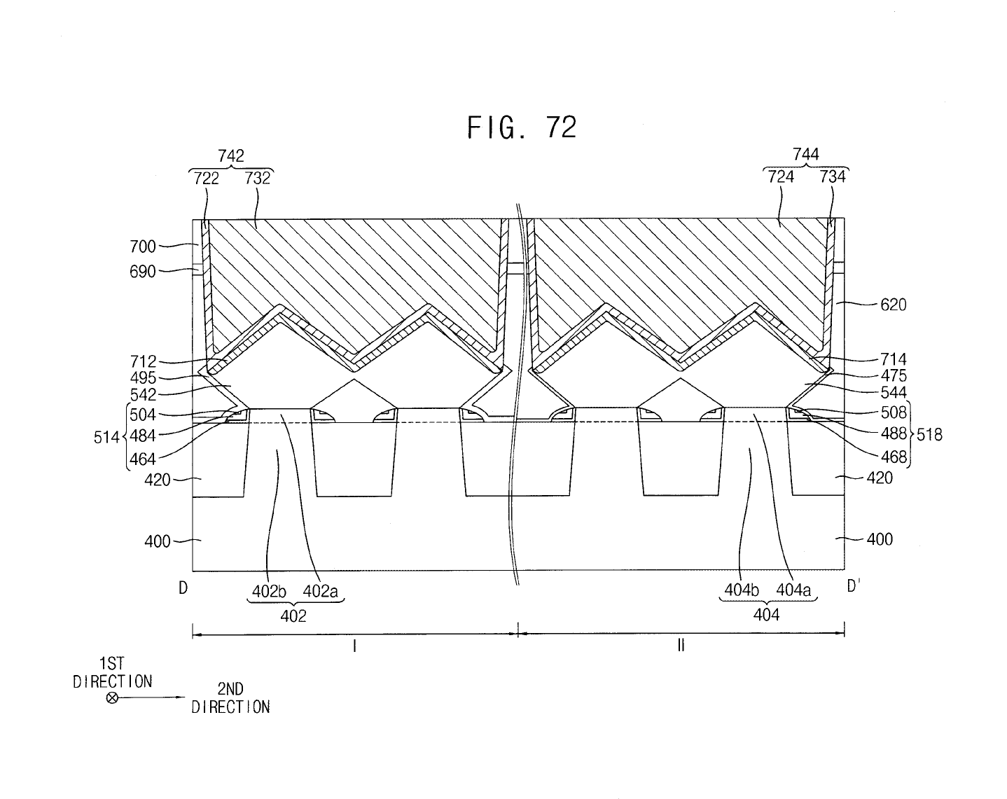

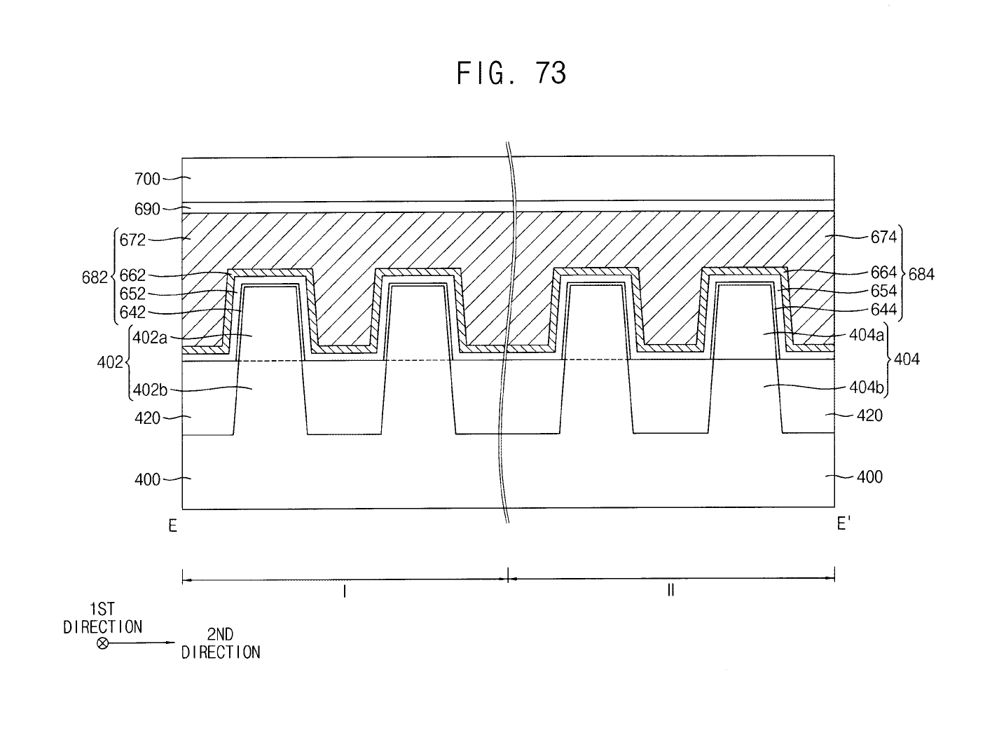

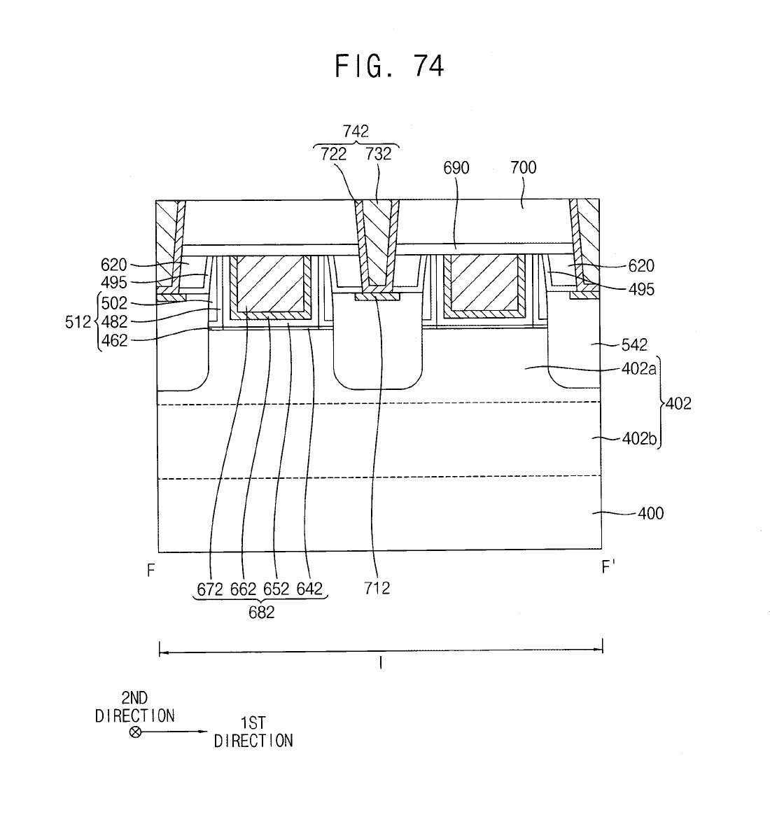

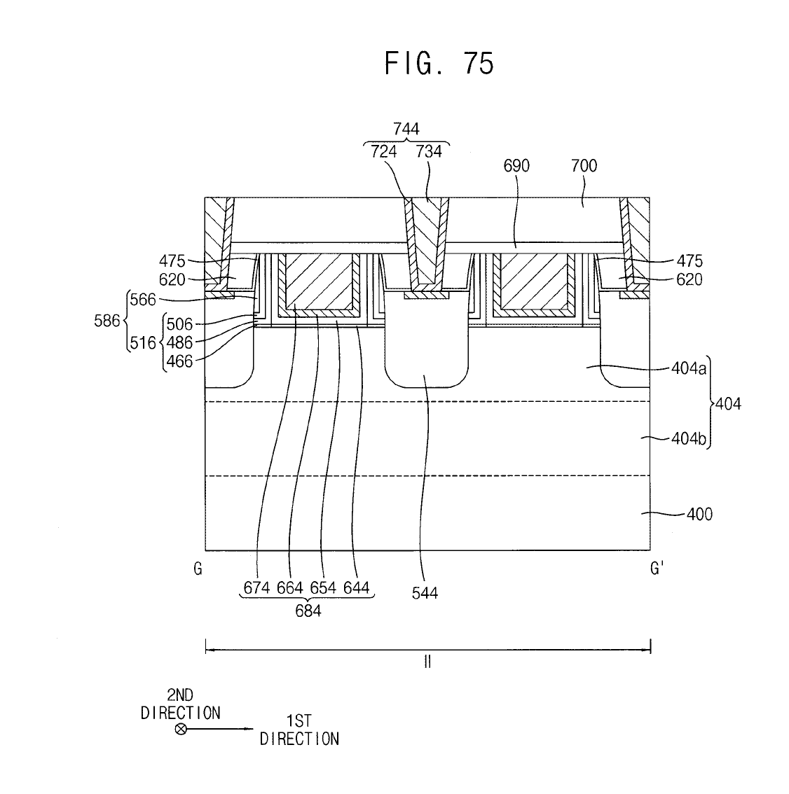

FIGS. 38 to 75 are plan views and cross-sectional views illustrating stages of a method of manufacturing a semiconductor device in accordance with example embodiments. Particularly, FIGS. 38, 40, 43, 49, 52, 56, 63, 67 and 71 are plan views, and FIGS. 39, 41-42, 44-48, 50-51, 53-55, 57-62, 64-66, 68-70 and 72-75 are cross-sectional views.

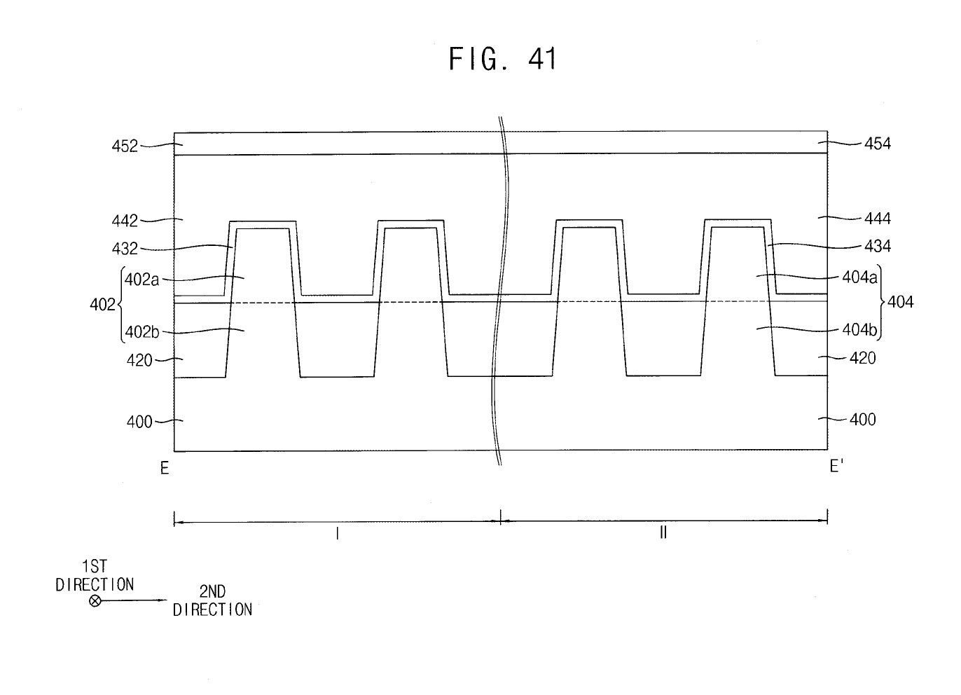

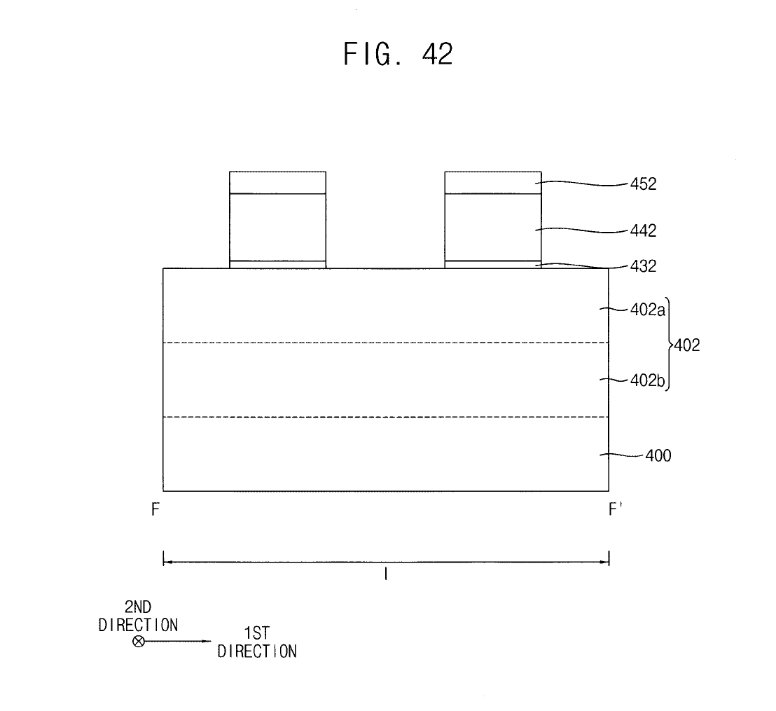

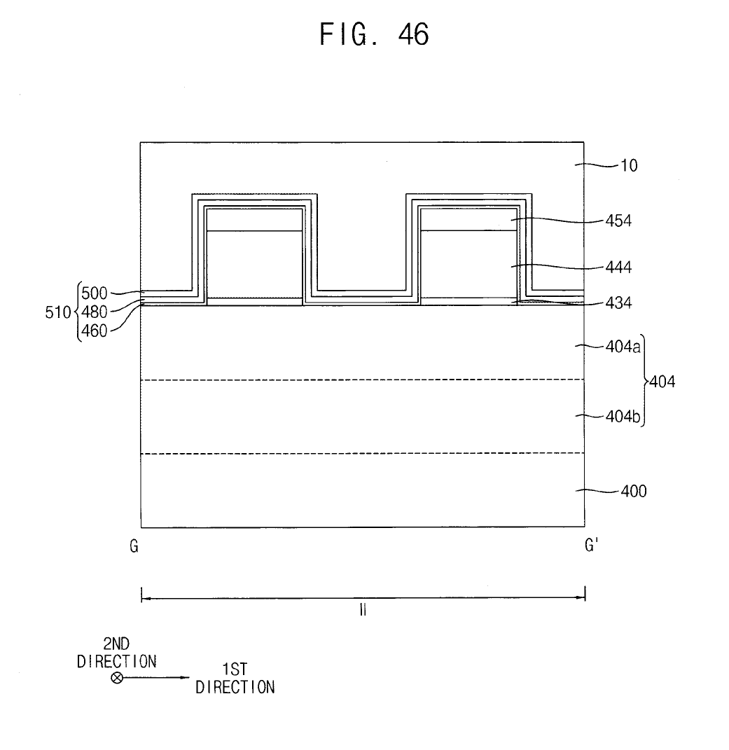

FIGS. 39, 44, 50, 53, 57, 60, 64 and 72 are cross-sectional views taken along lines D-D′ of corresponding plan views, respectively, FIGS. 41, 68 and 73 are cross-sectional views taken along lines E-E′ of corresponding plan views, respectively, FIGS. 42, 45, 47, 51, 54, 58, 61, 65, 69 and 74 are cross-sectional views taken along lines F-F′ of corresponding plan views, respectively, and FIGS. 46, 48, 55, 59, 62, 66, 70 and 75 are cross-sectional views taken along lines G-G′ of corresponding plan views.

This method is an application to a complementary metal oxide semiconductor (CMOS) transistor of the method illustrated with reference to FIGS. 1 to 36. Thus, the method may include processes substantially the same as or similar to those illustrated with reference to FIGS. 1 to 36, and detailed descriptions thereon are omitted herein.

Referring to FIGS. 38 and 39, processes substantially the same as or similar to those illustrated with reference to FIGS. 1 and 2 may be performed.

Thus, upper portions of a substrate 400 may be partially etched to form first and second recesses 412 and 414.

The substrate 400 may include first and second regions I and II. In example embodiments, the first region I may serve as a PMOS region, and the second region II may serve as an NMOS region.

As the first and second recesses 412 and 414 are formed on the substrate 400, first and second active regions 402 and 404 may be defined on the first and second regions I and II, respectively, of the substrate 400. The first and second active regions 402 and 404 may be also referred to as first and second active fins, respectively. A region of the substrate 400 on which no active fin is formed may be referred to as a field region.

In example embodiments, each of the first and second active regions 402 and 404 may extend in a first direction substantially parallel to an upper surface of the substrate 400, and a plurality of first active fins 402 and a plurality of second active fins 404 may be formed in a second direction, which may be substantially parallel to the upper surface of the substrate 400 and cross the first direction. In example embodiments, the first and second directions may cross each other at a right angle, and thus may be substantially perpendicular to each other.

An isolation pattern 420 may be formed on the substrate 400 to fill lower portions of the first and second recesses 412 and 414.

The first active fin 402 may include a first lower active pattern 402b whose sidewall may be covered by the isolation pattern 420, and a first upper active pattern 402a not covered by the isolation pattern 420 but protruding therefrom. The second active fin 404 may include a second lower active pattern 404b whose sidewall may be covered by the isolation pattern 420, and a second upper active pattern 404a not covered by the isolation pattern 420 but protruding therefrom.

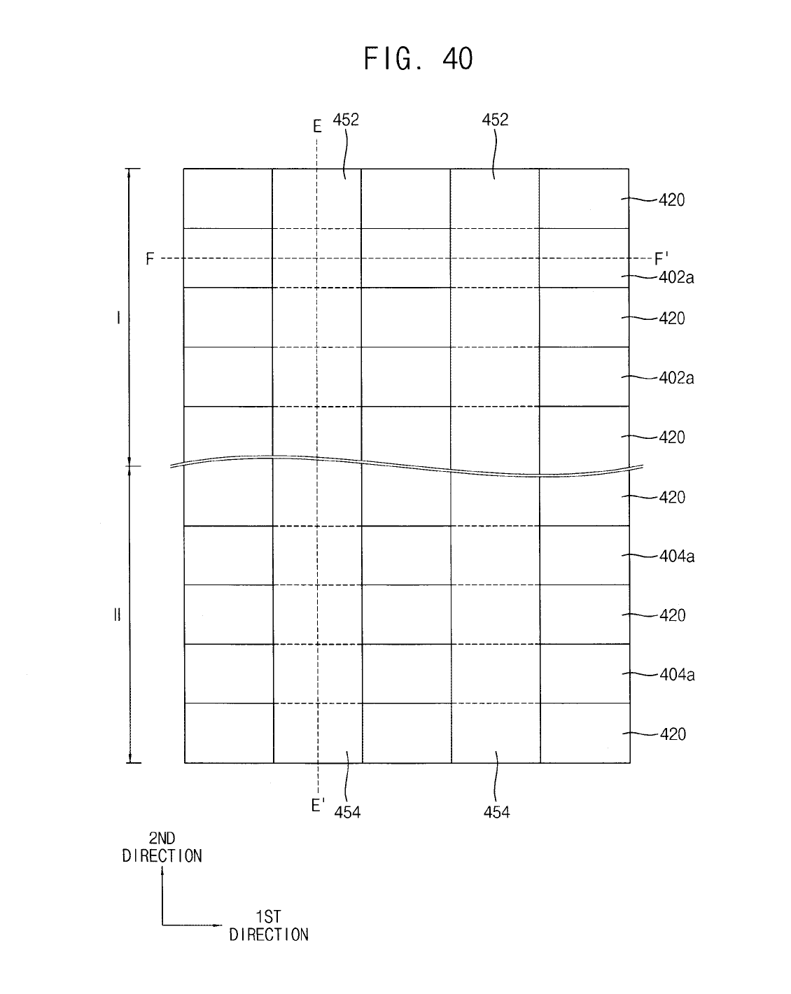

Referring to FIGS. 40 to 42, processes substantially the same as or similar to those illustrated with reference to FIGS. 3 to 5 may be performed to form first and second dummy gate structures on the first and second regions I and II, respectively, of the substrate 400.

The first dummy gate structure may include a first dummy gate insulation pattern 432, a first dummy gate electrode 442 and a first dummy gate mask 452 sequentially stacked on the first region I of the substrate 400, and the second dummy gate structure may include a second dummy gate insulation pattern 434, a second dummy gate electrode 444 and a second dummy gate mask 454 sequentially stacked on the second region II of the substrate 400.

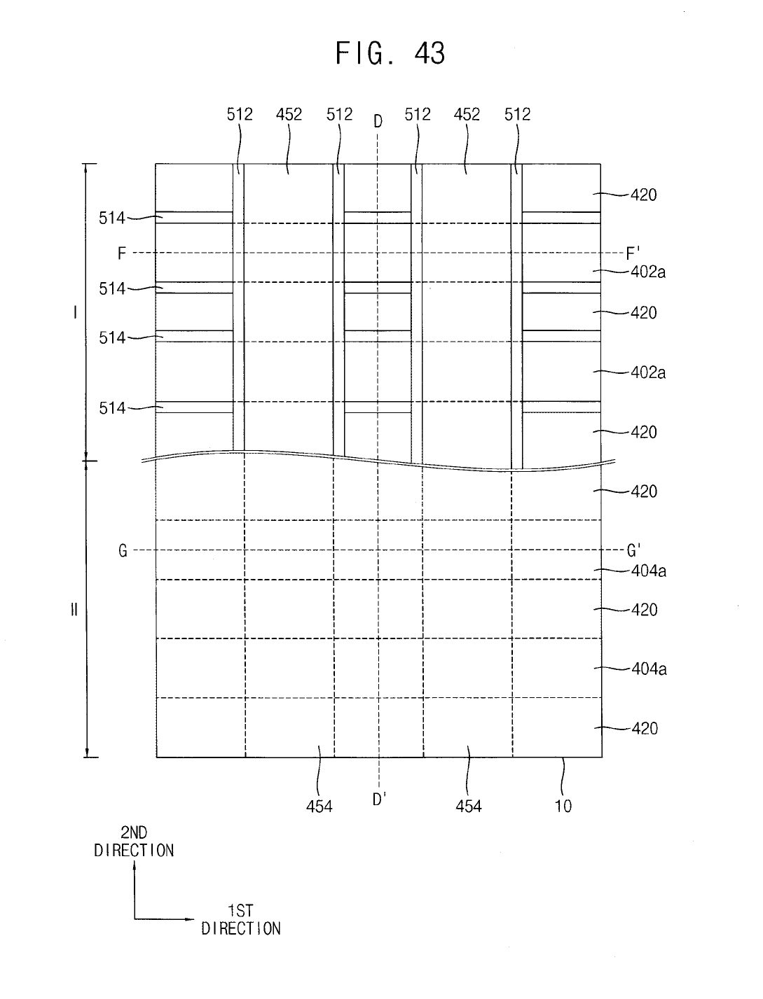

Referring to FIGS. 43 to 46, processes substantially the same as or similar to those illustrated with reference to FIGS. 6 to 8 may be performed to form a spacer layer structure 510 on the first and second active fins 402 and 404 and the isolation pattern 420 to cover the first and second dummy gate structures.

In example embodiments, the spacer layer structure 510 may include a diffusion prevention layer 460, a spacer layer 480, and a first offset layer 500 sequentially stacked.

The diffusion prevention layer 460 may be formed of, e.g., silicon nitride, the spacer layer 480 may be formed of e.g., silicon oxycarbonitride, and the first offset layer 500 may be formed of, e.g., silicon dioxide.

A first photoresist pattern 10 may be formed to cover the second region II of the substrate 400, and processes substantially the same as or similar to those illustrated with reference to FIGS. 9 to 11 may be performed to anisotropically etch the spacer layer structure 510.

Thus, a first gate spacer structure 512 may be formed on each of opposite sidewalls of the first dummy gate structure in the first direction on the first region I of the substrate 400, and a first fin spacer structure 514 may be formed on each of opposite sidewalls of the first upper active pattern 402a in the second direction on the first region I of the substrate 400.

The first gate spacer structure 512 may include a first diffusion prevention pattern 462, a first spacer 482, and a first offset pattern 502 sequentially stacked, and the first fin spacer structure 514 may include a second diffusion prevention pattern 464, a second spacer 484, and a second offset pattern 504 sequentially stacked.

A portion of the spacer layer structure 510 on the second region II of the substrate 400 may remain.

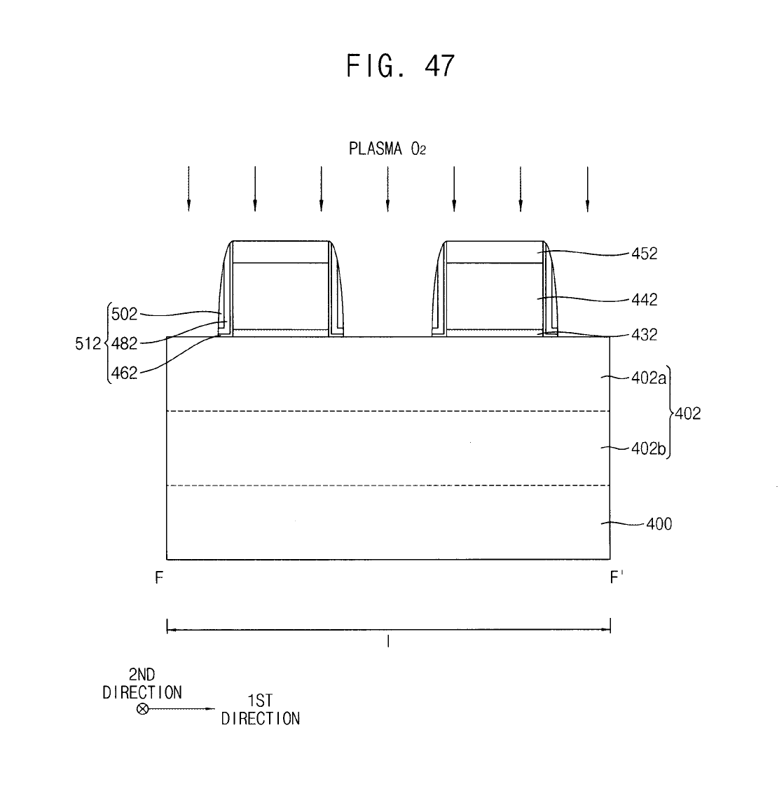

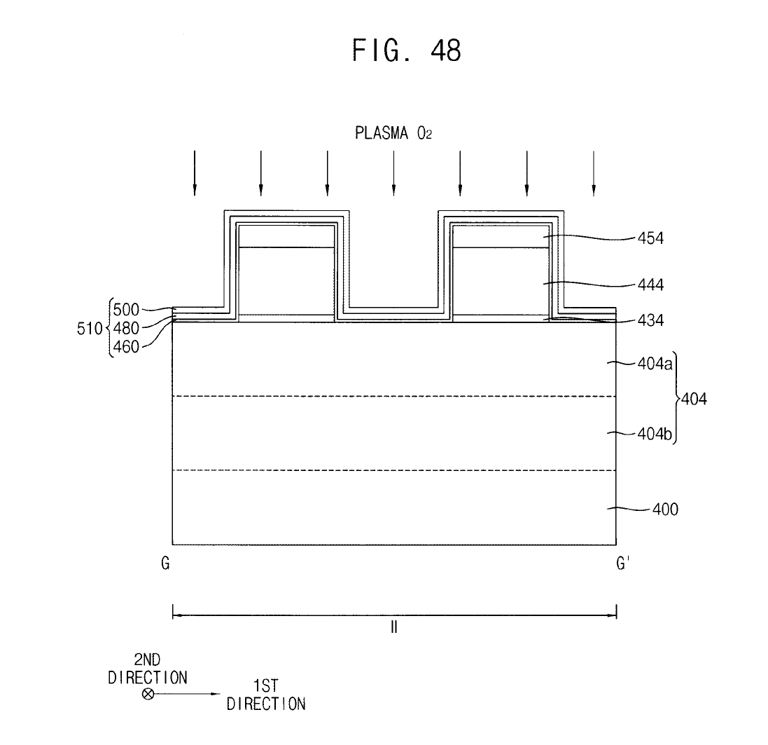

Referring to FIGS. 47 and 48, after removing the first photoresist pattern 10, processes substantially the same as or similar to those illustrated with reference to FIG. 12 may be performed.

Thus, a plasma treatment process may be performed on the substrate 400 using oxygen plasma such that the first and second offset patterns 502 and 504 including silicon oxide may be densified.

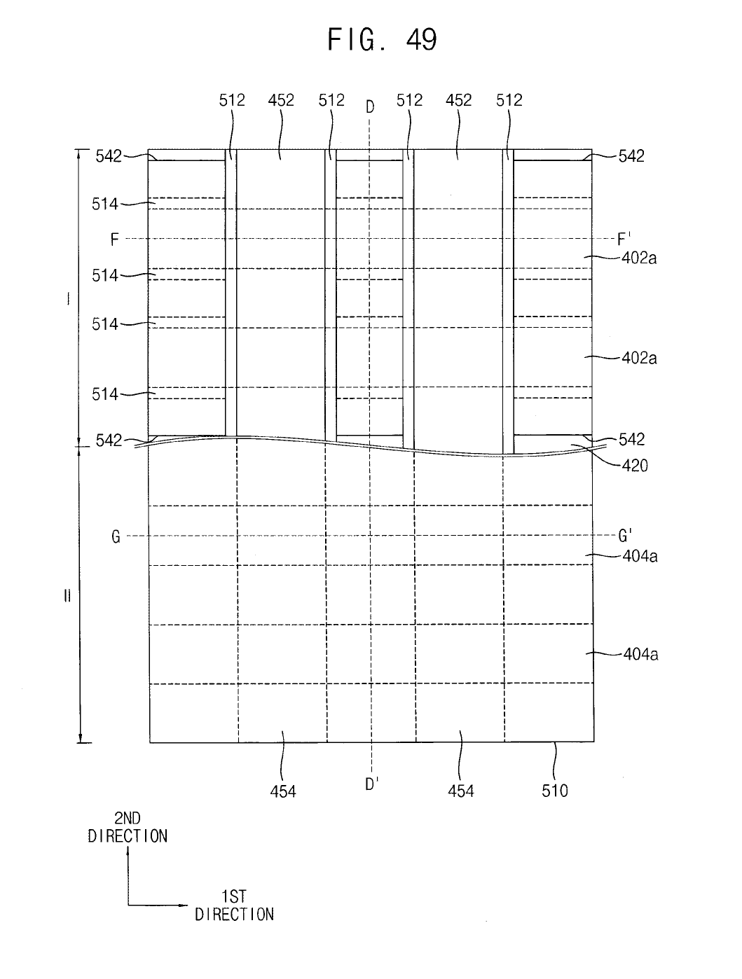

Referring to FIGS. 49 to 51, processes substantially the same as or similar to those illustrated with reference to FIGS. 13 to 15 may be performed.

An upper portion of the first active fin 402 adjacent the first gate spacer structure 512 may be etched to form a third recess (not shown). That is, the upper portion of the active fin 402 may be removed using the first dummy gate structure and the first gate spacer structure 512 on a sidewall thereof as an etching mask to form the third recess. When the third recess is formed, the first offset pattern 502 at an outermost portion of the gate spacer structure 512 may be rarely etched but remain, because the first offset pattern 502 has been densified by the plasma treatment process.

When the third recess is formed, the fin spacer structure 514 adjacent the active fin 402 may be mostly removed, and only a lower portion of the fin spacer structure 514 may remain. In example embodiments, a height of a top surface of the remaining fin spacer structure 514 may be equal to or lower than that of the active fin 402 under the third recess.

In the second region II of the substrate 400, even if the dry etching process for forming the third recess is performed, the first offset layer 500 at an outermost portion of the spacer layer structure 510 has been densified by the plasma treatment process, and thus may not be removed but remain.

A first source/drain layer 542 may be formed by a selective epitaxial growth (SEG) process using an upper surface of the first active fin 402 exposed by the third recess as a seed.

In example embodiments, the SEG process may be formed by providing a silicon source gas, a germanium source gas, an etching gas and a carrier gas, and thus a single crystalline silicon-germanium layer doped with p-type impurities may be formed to serve as the first source/drain layer 542. The first source/drain layer 542 may serve as a source/drain region of a PMOS transistor.

The spacer layer structure 510 may be formed on the second active fin 404 on the second region II of the substrate 400, and thus no source/drain layer may be formed by the SEG process.

Referring to FIGS. 52 to 54, processes substantially the same as or similar to those illustrated with reference to FIGS. 17 to 19 may be performed.

First, a growth prevention layer structure 570 may be formed on the first source/drain layer 542, the isolation pattern 420, the first dummy gate structure, the first gate spacer structure 512 and the first fin spacer structure 514 on the first region I of the substrate 400, and on the spacer layer structure 510 on the second region II of the substrate 400.

In example embodiments, the growth prevention layer structure 570 may include a growth prevention layer 550 and a second offset layer 560 sequentially stacked.

The growth prevention layer 550 may be formed of, e.g., silicon nitride, and the second offset layer 560 may be formed of, e.g., silicon dioxide.

A second photoresist pattern 20 may be formed to cover the first region I of the substrate 400, and processes substantially the same as or similar to those illustrated with reference to FIGS. 13 to 15 may be performed to anisotropically etch the spacer layer structure 510 and the growth prevention layer structure 570 sequentially stacked on the second region II of the substrate 400.

Thus, a second gate spacer structure 516 and a first growth prevention pattern structure 576 may be sequentially stacked on each of opposite sidewalls of the second dummy gate structure in the first direction on the second region II of the substrate 400, and a second fin spacer structure 518 and a second growth prevention pattern structure 578 may be sequentially stacked on each of opposite sidewalls of the second upper active pattern 404a in the second direction on the second region II of the substrate 400.

The second gate spacer structure 516 may include a third diffusion prevention pattern 466, a third spacer 486 and a third offset pattern 506 sequentially stacked, and the second fin spacer structure 518 may include a fourth diffusion prevention pattern 468, a fourth spacer 488 and a fourth offset pattern 508 sequentially stacked. Additionally, the first growth prevention pattern structure 576 may include a first growth prevention pattern 556 and a fifth offset pattern 566 sequentially stacked, and the second growth prevention pattern 578 may include a second growth prevention pattern 558 and a sixth offset pattern 568 sequentially stacked.

A portion of the growth prevention layer structure 570 on the first region I of the substrate 400 may remain.

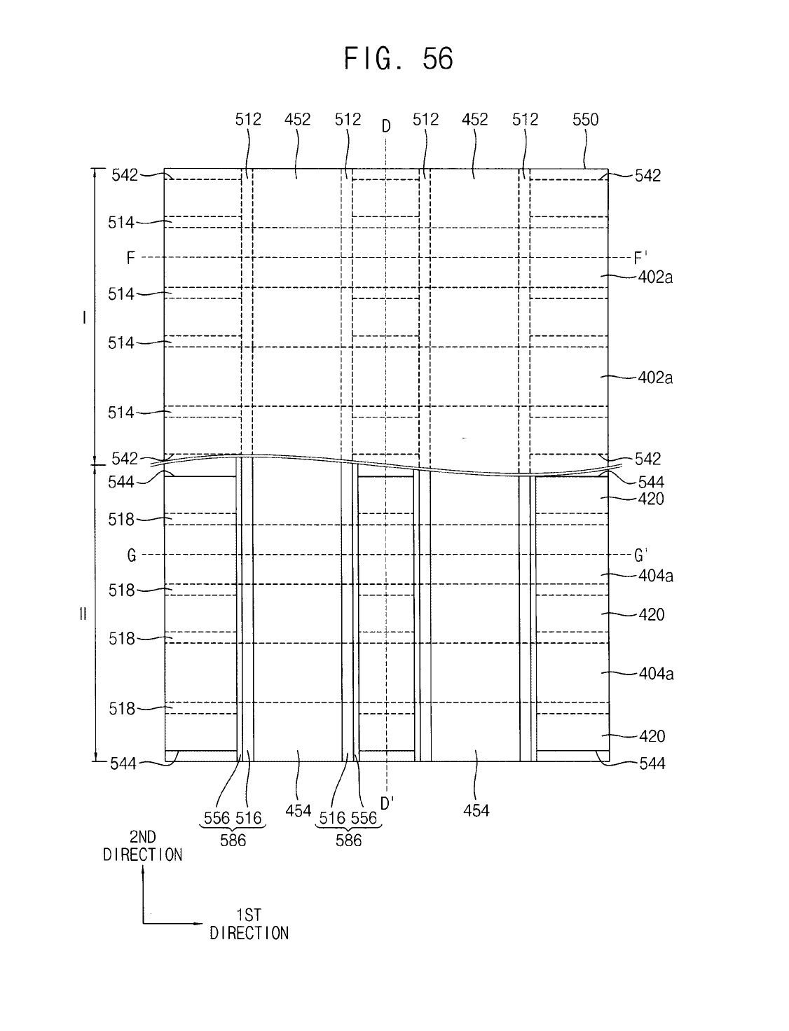

Referring to FIGS. 56 to 59, processes substantially the same as or similar to those illustrated with reference to FIGS. 49 to 51 may be performed.

First, after removing the second photoresist pattern 20, an upper portion of the second active fin 404 may be etched using the second dummy gate structure, and the second gate spacer structure 516 and the first growth prevention pattern structure 576 on a sidewall of the second dummy gate structure as an etching mask to form a fourth recess (not shown). The fifth offset pattern 566 including silicon dioxide, which may be easily removed in a dry etching process, may be removed, however, the first growth prevention pattern 556 including silicon nitride, which may not be easily removed in a dry etching process, may not be removed but remain. Thus, a third gate spacer structure 586 including the second gate spacer structure 516 and the first growth prevention pattern 556 sequentially stacked may be formed on the sidewall of the second dummy gate structure.

When the fourth recess is formed, the second fin spacer structure 518 and the second growth prevention pattern 578 adjacent the second active fin 404 may be mostly removed, and only a portion of the second fin spacer structure 518 may remain. In example embodiments, a height of a top surface of the remaining second fin spacer structure 518 may be equal to or lower than that of the second active fin 404 under the fourth recess.

During the dry etching process for forming the fourth recess, the second offset layer 560 including silicon dioxide in the growth prevention layer structure 570 may be removed, and the growth prevention layer 550 may remain on the first region I of the substrate 400.

A second source/drain layer 544 may be formed by an SEG process using an upper surface of the second active fin 404 exposed by the fourth recess as a seed.

In example embodiments, the SEG process may be formed by providing a silicon source gas, a carbon source gas, an n-type impurity source gas, an etching gas and a carrier gas, and thus a single crystalline silicon carbide layer doped with n-type impurities may be formed to serve as the second source/drain layer 544. Alternatively, the SEG process may be formed by providing a silicon source gas, an n-type impurity source gas, an etching gas and a carrier gas, and thus a single crystalline silicon layer doped with n-type impurities may be formed to serve as the second source/drain layer 544. The second source/drain layer 544 may serve as a source/drain region of an NMOS transistor.

The growth prevention layer 550 may be formed on the first active fin 402 in the first region I of the substrate 400, and thus no source/drain layer may be formed by the SEG process.

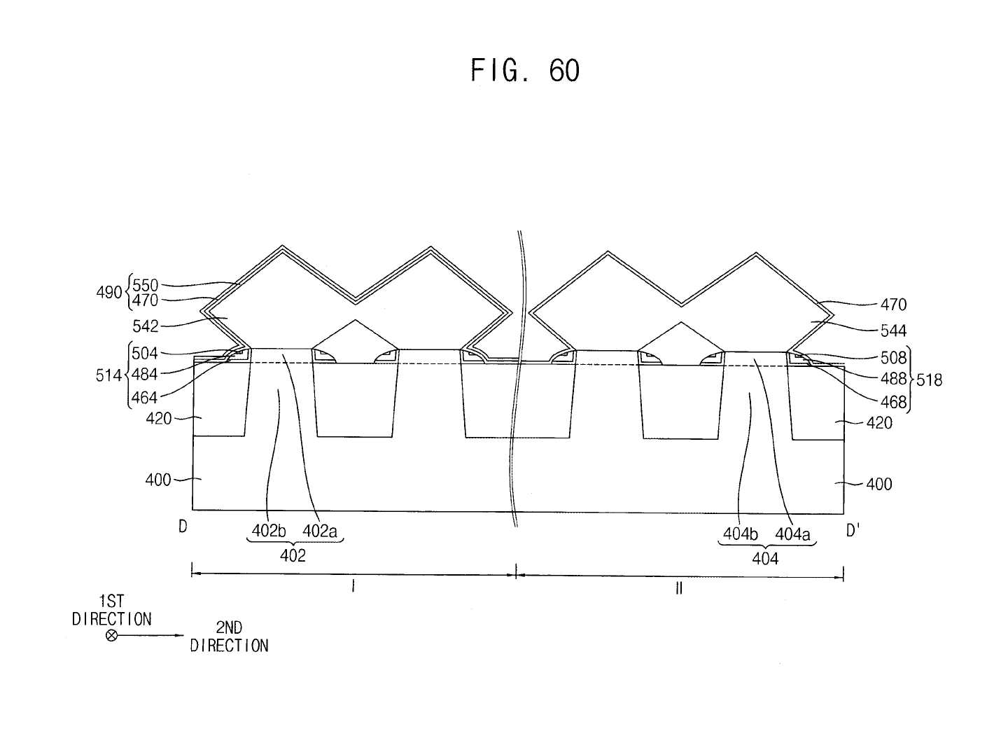

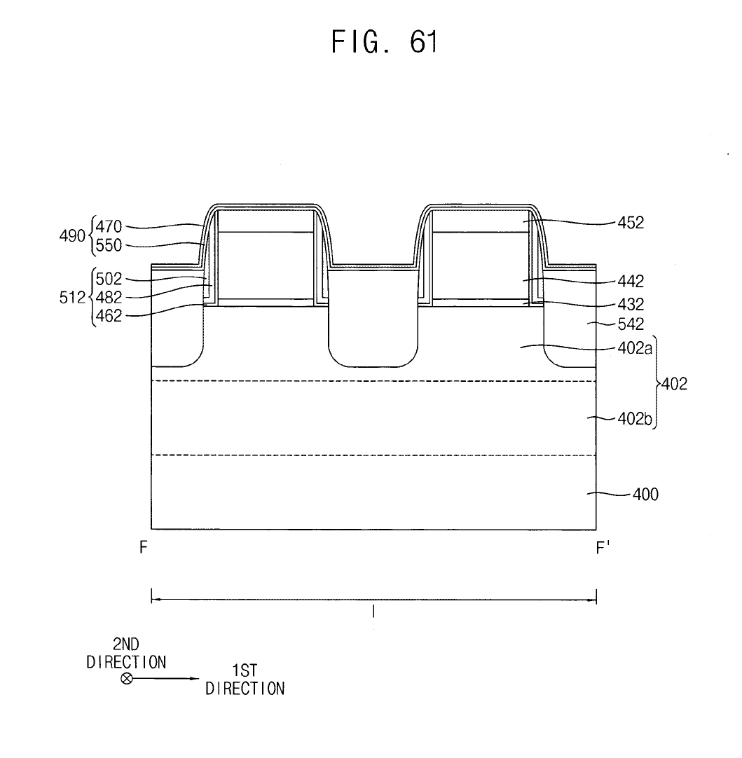

Referring to FIGS. 60 to 62, processes substantially the same as or similar to those illustrated with reference to FIGS. 20 and 21 may be performed.

Thus, a first etch stop layer 470 may be formed on the growth prevention layer 550 on the first region I of the substrate 400, and the second dummy gate structure, the third gate spacer structure 586, the second fin spacer structure 518, the second source/drain layer 544 and the isolation pattern 420 on the second region II of the substrate 400.

In example embodiments, the first etch stop layer 470 may be formed of a nitride, e.g., silicon nitride. Thus, the first etch stop layer 470 and the growth prevention layer 550 may be merged with each other on the first region I of the substrate 400, and hereinafter, the merged layer structure may be referred to as a second etch stop layer 490.

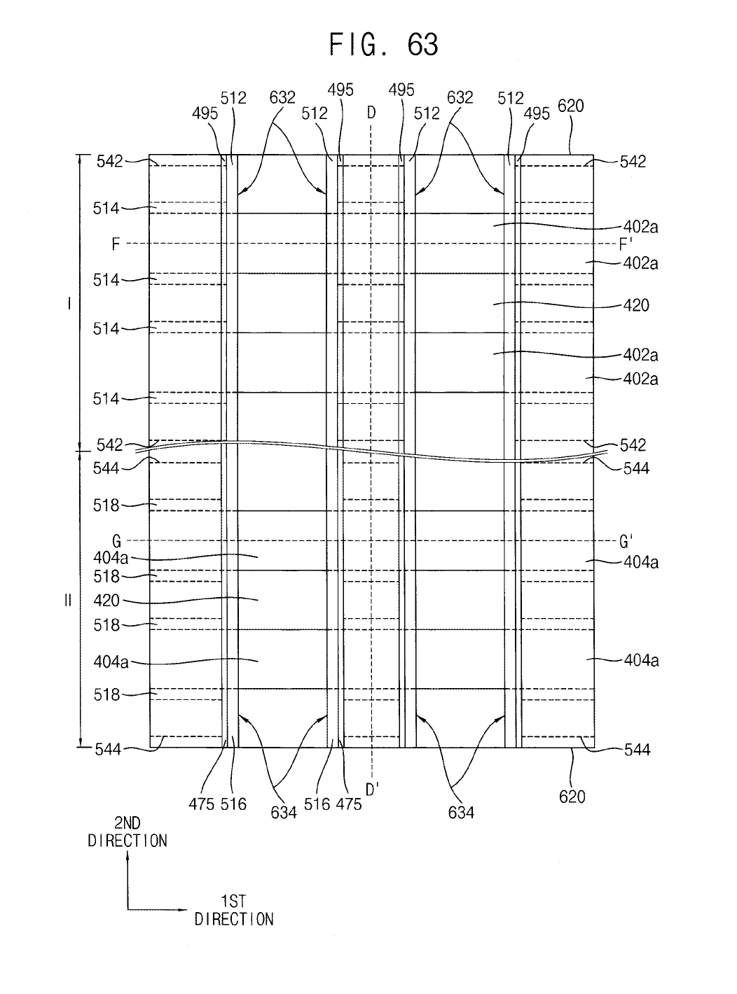

Referring to FIGS. 63 to 66, processes substantially the same as or similar to those illustrated with reference to FIGS. 22 to 26 may be performed.

First, an insulation layer 620 may be formed on the first and second etch stop layers 470 and 490 to a sufficient height, and may be planarized until upper surfaces of the first and second dummy gate electrodes 442 and 444 of the respective first and second dummy gate structures may be exposed.

In the planarization process, the first and second dummy gate masks 452 and 454 may be removed, and portions of the first and second etch stop layers 470 and 490 on upper surfaces of the first and second dummy gate masks 452 and 454, respectively, may be removed to form first and second etch stop patterns 475 and 495, respectively. Thus, the first etch stop pattern 475 may be formed on an upper sidewall of the third gate spacer structure 586, a sidewall of the second fin spacer structure 518 and an upper surface of the second source/drain layer 544, and the second etch stop pattern 495 may be formed on an upper sidewall of the first gate spacer structure 512, a sidewall of the first fin spacer structure 514 and an upper surface of the first source/drain layer 542.

A space between the merged first source/drain layers 542 and the isolation pattern 420 and a space between the merged second source/drain layers 544 and the isolation pattern 420 may not be filled with the insulation layer 620, and thus first and second air gaps 622 and 624 may be formed, respectively.

The exposed first and second dummy gate electrodes 442 and 444 and the first and second dummy gate insulation patterns 432 and 434 thereunder may be removed to form a first opening 632 exposing an inner sidewall of the first gate spacer structure 512 and an upper surface of the first active fin 402, and to form a second opening 634 exposing an inner sidewall of the third gate spacer structure 586 and an upper surface of the second active fin 404.

The first and second dummy gate electrodes 442 and 444 and the first and second dummy gate insulation patterns 432 and 434 thereunder may be removed by a dry etching process and a wet etching process, and the first and third diffusion prevention patterns 462 and 466 may be partially removed to expose the first and third spacers 482 and 486, respectively.

Portions of the first and third diffusion prevention patterns 462 and 466 on sidewalls of the respective first and third spacers 482 and 486 may be mostly removed. However, portions of the first and third diffusion prevention patterns 462 and 466 on upper surfaces of the respective first and second active fins 402 and 404 may not be completely removed but at least partially remain.

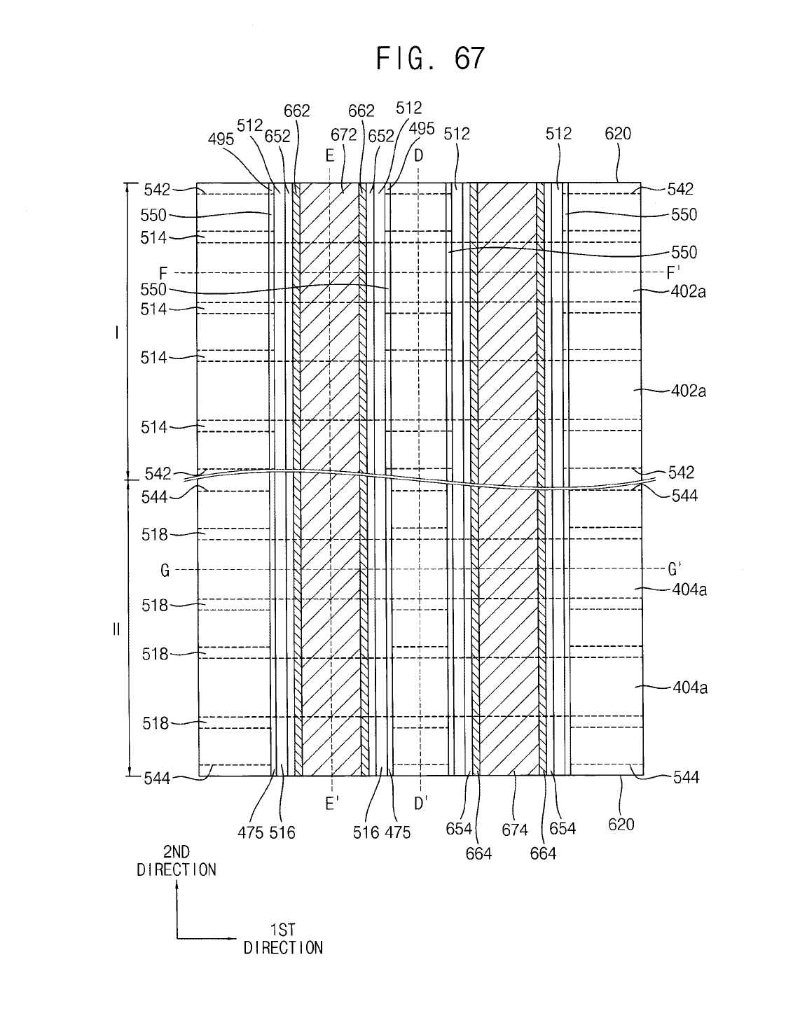

Referring to FIGS. 67 to 70, processes substantially the same as or similar to those illustrated with reference to FIGS. 27 to 29 may be performed to form first and second gate structures 682 and 684 in the first and second openings 632 and 634, respectively.

The first gate structure 682 may include a first interface pattern 642, a first gate insulation pattern 652, a first work function control pattern 662 and a first gate electrode 672 sequentially stacked, and the first gate structure 682 together with the first source/drain layer structure 542 may form a PMOS transistor. The second gate structure 684 may include a second interface pattern 644, a second gate insulation pattern 654, a second work function control pattern 664 and a second gate electrode 674 sequentially stacked, and the second gate structure 684 together with the second source/drain layer structure 544 may form an NMOS transistor.

Up to now, after the PMOS transistor is formed on the first region I of the substrate 400, the NMOS transistor is formed on the second region II of the substrate 400, however, example embodiments of the inventive concepts may not be limited thereto. That is, after the NMOS transistor is formed on the first region I of the substrate 400, and the PMOS transistor may be formed on the second region II of the substrate 400.

The first gate spacer structure 512 including the first diffusion prevention pattern 462, the first spacer 482 and the first offset pattern 502 sequentially stacked may be formed on each of opposite sidewalls of the first gate structure 682 in the first direction, and the second etch stop pattern 495 may be formed on the upper sidewall of the first gate spacer structure 512 and the first source/drain layer 542.

The third gate spacer structure 586 having the second gate spacer structure 516 including the third diffusion prevention pattern 466, the third spacer 486 and the third offset pattern 506 sequentially stacked on each of opposite sidewalls of the second gate structure 684 in the first direction, and the first growth prevention pattern 556 on the second gate spacer structure 516 may be formed. The first etch stop pattern 475 may be formed on the upper sidewall of the third gate spacer structure 586 and the second source/drain layer 544.

Referring to FIGS. 71 to 75, processes substantially the same as or similar to those illustrated with reference to FIGS. 30 to 36 may be performed to complete the semiconductor device.

Thus, a capping layer 690 and an insulating interlayer 700 may be sequentially formed on the insulation layer 620, the first and second gate structures 682 and 684, the first and second etch stop patterns 475 and 495, and the first and third gate spacer structures 512 and 586, and first and second contact holes (not shown) may be formed through the insulating interlayer 700, the capping layer 690, the insulation layer 620 and the first and second etch stop patterns 495 and 475, and to expose upper surfaces of the first and second source/drain layer structures 542 and 544, respectively.

The first and second contact holes may be or may not be self-aligned with the first and third gate spacer structures 512 and 586, respectively.

After forming a first metal layer on the exposed upper surfaces of the first and second source/drain layer structures 542 and 544, sidewalls of the first and second contact holes, and the upper surface of the insulating interlayer 700, a heat treatment process may be performed thereon to form first and second metal silicide patterns 712 and 714 on the first and second source/drain layer structures 542 and 544, respectively. An unreacted portion of the first metal layer may be removed.

A barrier layer may be formed on upper surfaces of the first and second metal silicide patterns 712 and 714, the sidewalls of the first and second contact holes, and the upper surface of the insulating interlayer 700, a second metal layer may be formed on the barrier layer to fill the first and second contact holes, and the second metal layer and the barrier layer may be planarized until the upper surface of the insulating interlayer 700 may be exposed. Thus, first and second contact plugs 742 and 744 may be formed on the first and second metal silicide patterns 712 and 714, respectively.

The first contact plug 742 may include a first metal pattern 732 and a first barrier pattern 722 covering a lower surface and a sidewall thereof, and the second contact plug 744 may include a second metal pattern 734 and a second barrier pattern 724 covering a lower surface and a sidewall thereof.

A wiring (not shown) and a via (not shown) may be further formed to be electrically connected to the first and second contact plugs 742 and 744.

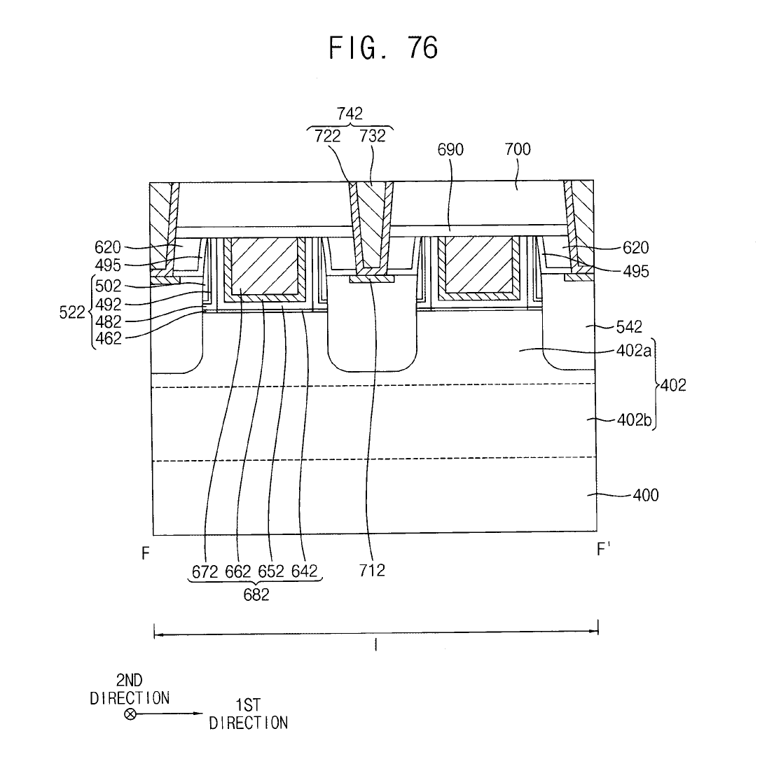

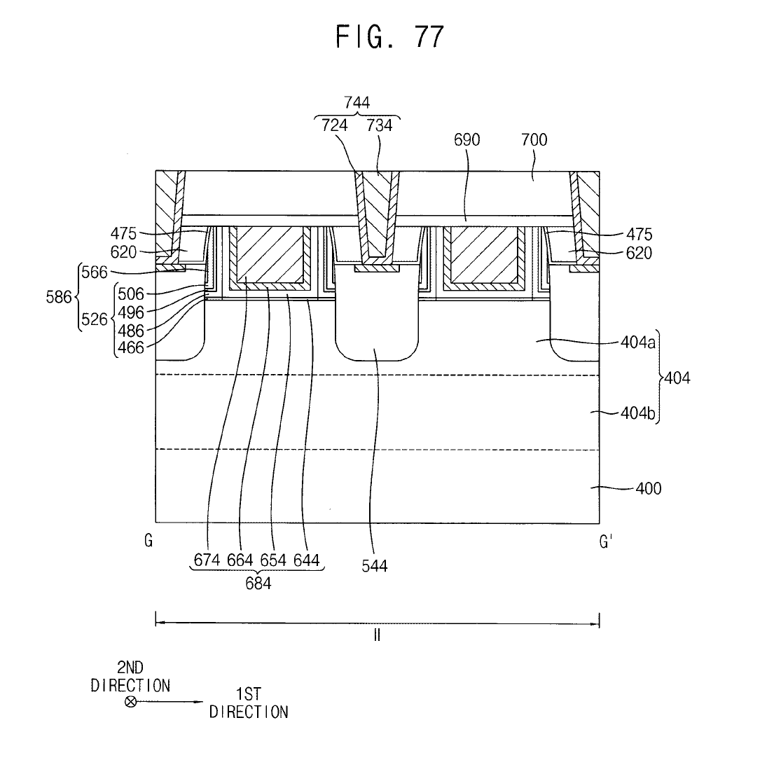

FIGS. 76 and 77 are cross-sectional views illustrating a semiconductor device in accordance with example embodiments. The semiconductor device may be substantially the same as or similar to that of FIGS. 71 to 75, except for the first and second gate spacer structures. Thus, like reference numerals refer to like elements, and detailed descriptions thereon are omitted herein.

Referring to FIGS. 76 and 77, a first gate spacer structure 522 may further include a first outgassing prevention pattern 492 between the first spacer 482 and the first offset pattern 502. Additionally, a second gate spacer structure 526 may further include a second outgassing prevention pattern 496 between the third spacer 486 and the third offset pattern 506.

In example embodiments, each of the first and second outgassing prevention patterns 492 and 496 may include silicon nitride, and may include a cross-section taken along the first direction having an L-like shape.

The above method of manufacturing the semiconductor device may be applied to methods of manufacturing various types of memory devices including spacers on sidewalls of gate structures. For example, the method may be applied to methods of manufacturing logic devices such as central processing units (CPUs), main processing units (MPUs), or application processors (APs), or the like. Additionally, the method may be applied to methods of manufacturing volatile memory devices such as DRAM devices or SRAM devices, or non-volatile memory devices such as flash memory devices, PRAM devices, MRAM devices, RRAM devices, or the like.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the example embodiments of the inventive concepts. Accordingly, all such modifications are intended to be included within the scope of the example embodiments of the inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
an active fin on a substrate;
a gate structure on the active fin;
a gate spacer structure directly on a sidewall of the gate structure, the gate spacer structure including a silicon oxycarbonitride (SiOCN) pattern and a silicon dioxide (SiO₂) pattern sequentially stacked; and
a source/drain layer on a portion of the active fin adjacent the gate spacer structure.

2. The semiconductor device of claim 1, further comprising:
a first silicon nitride pattern between the silicon oxycarbonitride pattern and the silicon dioxide pattern.

3. The semiconductor device of claim 2, wherein the first silicon nitride pattern includes a cross-section taken along a direction having an L-like shape.

4. The semiconductor device of claim 1, wherein the silicon oxycarbonitride pattern contacts an upper sidewall of the gate structure, and the semiconductor device further comprises:
a second silicon nitride pattern below the silicon oxycarbonitride pattern relative to the substrate, the second silicon nitride pattern contacting a lower sidewall of the gate structure.

5. The semiconductor device of claim 4, wherein
the silicon oxycarbonitride pattern includes a cross-section taken along a direction having an L-like shape,
the second silicon nitride pattern contacts a bottom of the silicon oxycarbonitride pattern, and
the second silicon nitride pattern includes a cross-section taken along the direction having a bar shape.

6. The semiconductor device of claim 1, wherein the silicon oxycarbonitride pattern includes a cross-section taken along a direction having an L-like shape.

7. The semiconductor device of claim 1, further comprising:
a third silicon nitride pattern on an upper sidewall of the silicon dioxide pattern.

8. The semiconductor device of claim 7, wherein
the third silicon nitride pattern has a cross-section taken along a direction having an L-like shape,
a sidewall of the third silicon nitride pattern contacts an upper sidewall of the silicon dioxide pattern, and
a bottom of the third silicon nitride pattern contacts an upper surface of the source/drain layer.

9. The semiconductor device of claim 7, wherein a thickness of the silicon dioxide pattern is greater than or equal to a thickness of the third silicon nitride pattern.

10. The semiconductor device of claim 1, wherein the gate structure comprises:
an interface pattern on the active fin;
a gate insulation pattern on an upper surface of the interface pattern and a sidewall of the silicon oxycarbonitride pattern;
a work function control pattern on the gate insulation pattern; and
a gate electrode on the work function control pattern.

11. A semiconductor device, comprising:
an active fin on a substrate;
a gate structure on the active fin;
a gate spacer structure on the active fin such that the gate spacer structure covers a sidewall of the gate structure, the gate spacer structure including,
a diffusion prevention pattern on the active fin,
a silicon oxycarbonitride pattern on the diffusion prevention pattern, the silicon oxycarbonitride pattern including a cross-section taken along a direction having an L-like shape,
an outgassing prevention pattern on the silicon oxycarbonitride pattern, the outgassing prevention pattern including a cross-section taken along the direction having an L-like shape, and
an offset pattern on the outgassing prevention pattern; and
a source/drain layer on a portion of the active fin adjacent the gate spacer structure.

12. The semiconductor device of claim 11, wherein the diffusion prevention pattern, the outgassing prevention pattern, and the offset pattern include silicon nitride, silicon nitride, and silicon oxide, respectively.

13. The semiconductor device of claim 11, wherein
the diffusion prevention pattern contacts a lower sidewall of the gate structure, and
the silicon oxycarbonitride pattern contacts an upper sidewall of the gate structure.

14. The semiconductor device of claim 11, further comprising:
an etch stop pattern covering an upper sidewall of the offset pattern and an upper surface of the source/drain layer.

15. The semiconductor device of claim 14, wherein the etch stop pattern includes silicon nitride.

16. A semiconductor device comprising:
a substrate;
an active region protruding from an upper surface of the substrate; and
a gate spacer on a sidewall of a gate, the gate spacer being a multi-layer structure including an offset pattern having silicon dioxide.

17. The semiconductor device of claim 16, wherein the offset pattern is configured to compensate for a thickness of the gate spacer.

18. The semiconductor device of claim 17, wherein a thickness of the offset pattern is between 2-4 nm such that the thickness of the offset pattern is greater than or equal to a thickness of an etch stop pattern on at least an upper sidewall of the gate spacer.

19. The semiconductor device of claim 16, wherein the multi-layer structure of the gate spacer further includes a diffusion prevention pattern and a first spacer sequentially stacked below the offset pattern relative to the substrate, and the semiconductor device further comprises:
an outgassing prevention pattern on the first spacer, the outgassing prevention pattern configured to reduce an amount of carbon outgassing from the first spacer.

20. The semiconductor device of claim 16, wherein the offset pattern is densified.
